(19) United States
(12) Patent Application Publication
(10) Pub. No.: US 2019/0096729 A1
(43) Pub. Date: Mar. 28, 2019

(54) SUBSTRATE INVERTING DEVICE, SUBSTRATE PROCESSING APPARATUS, AND SUBSTRATE CATCH-AND-HOLD DEVICE

(71) Applicant: SCREEN Holdings Co., Ltd., Kyoto (JP)

(72) Inventor: Ryo MURAMOTO, Kyoto (JP)

(21) Appl. No.: 16/112,893

(22) Filed: Aug. 27, 2018

(30) Foreign Application Priority Data
Sep. 25, 2017 (JP) 2017-183211

(51) Int. Cl. H01L 21/677; H01L 21/67; H01L 21/687

(52) U.S. Cl. CPC H01L 21/67796; H01L 21/68764; H01L 21/67046

(57) ABSTRACT

In a substrate inverting device, each lower guide has a downward inclined plane that comes in contact with a peripheral edge portion of a substrate held in a horizontal position to support the substrate from below. Each upper guide has an upward inclined plane that comes in contact with the peripheral edge portion of the substrate to catch and hold the substrate between the lower guides and the upper guides. Each lower guide includes first and second lower contact regions that are switched by a switching mechanism and selectively serve as the downward inclined plane. Each upper guide includes first and second upper contact regions that are switched by the switching mechanism and selectively serve as the upward inclined plane. This allows the regions of contact between the upper and lower guides and the substrate in accordance with the state of the substrate.

### TECHNICAL FIELD

The present invention relates to a substrate inverting device, a substrate processing apparatus, and a substrate catch-and-hold device.

### BACKGROUND ART

A process of manufacturing semiconductor substrates (hereinafter, simply referred to as “substrates”) conventionally involves various types of processing that is performed on substrates. For example, the substrate processing apparatus disclosed in Japanese Patent Application Laid-Open No. 2013-46022 (Document 1) performs processing on the front and back surfaces of substrates. In the substrate processing apparatus, substrates with their front surfaces facing upward are transported from a carrier into an inverting path, inverted upside down by the inverting path, and then transported to a processing unit. The substrates that have undergone back-surface processing performed in the processing unit is transported again into the inverting path, inverted upside down, and then transported to a carrier.

The inverting path includes chucks that catch and hold substrates in a horizontal position. Each chuck includes two sets of upper and lower guide parts. The upper and lower guides that are aligned in the up-down direction form a V-shaped holding groove that opens toward the center of a substrate. The peripheral edge portion of the substrate is disposed inside the holding groove. The upper and lower guide parts advance or retract in the radial direction of the substrate so as to come in contact with the peripheral edge portion of the substrate or to be spaced radially outward from the peripheral edge portion of the substrate.

Incidentally, in the substrate processing apparatus of Document 1, unprocessed substrates and processed substrates are inverted by one and the same inverting path. In the case where one and the same inverting path is used in this manner to invert substrates irrespective of the states (e.g., unprocessed or processed) of the substrates, grime, particles, or the like on the unprocessed substrates may adhere to the chucks of the inverting path and may be transferred to the processed substrates.

### SUMMARY OF INVENTION

The present invention is intended for a substrate inverting device, and it is an object of the present invention to switch regions of contact between guide parts and a substrate in accordance with the state of the substrate.

A substrate inverting device according to a preferable embodiment of the present invention includes a plurality of lower guides each having a downward inclined plane that is inclined downward toward an inner side in a width direction of a substrate and that comes in contact with a peripheral edge portion of the substrate held in a horizontal position to support the substrate from below, a plurality of upper guides each having an upward inclined plane that is inclined upward toward the inner side in the width direction and that comes in contact with the peripheral edge portion of the substrate at a position above a position of contact between the substrate and the plurality of lower guides to catch and hold the substrate between the plurality of lower guides and the plurality of upper guides, an inversion mechanism that inverts the substrate that is caught and held by the plurality of lower guides and the plurality of upper guides, by rotating the plurality of lower guides and the plurality of upper guides about a central axis pointing in the horizontal direction, a guide moving mechanism that advances and retracts the plurality of lower guides and the plurality of upper guides between contact positions and retracted positions, the contact positions being positions at which the plurality of lower guides and the plurality of upper guides are in contact with the substrate, and the retracted positions being positions that are further away from the substrate than the contact positions, and a switching mechanism that changes states of contact between the plurality of lower guides and the substrate and between the plurality of upper guides and the substrate. Each lower guide includes a first lower contact region and a second lower contact region that are switched by the switching mechanism and selectively serve as the downward inclined plane. Each upper guide includes a first upper contact region and a second upper contact region that are switched by the switching mechanism and selectively serve as the upward inclined plane. With the substrate inverting device, the regions of contact between the upper and lower guides and the substrate can be switched in accordance with the state of the substrate.

Preferably, the first lower contact region and the second lower contact region of each lower guide are disposed at the same position in a longitudinal direction of a lower rotary shaft that extends in the width direction. The first upper contact region and the second upper contact region of each upper guide are disposed at the same position in a longitudinal direction of an upper rotary shaft that extends in the width direction. The switching mechanism includes a lower guide rotation mechanism that rotates each lower guide about the lower rotary shaft to make the first lower contact region and the second lower contact region selectively serve as the downward inclined plane, and an upper guide rotation mechanism that rotates each upper guide about the upper rotary shaft to make the first upper contact region and the second upper contact region selectively serve as the upward inclined plane.

Preferably, the first lower contact region and the second lower contact region of each lower guide are disposed at positions that have line symmetry with respect to a lower rotary shaft that extends in an up-down direction. The first upper contact region and the second upper contact region of each upper guide are disposed at positions that have line symmetry with respect to an upper rotary shaft that extends in the up-down direction. The switching mechanism includes a lower guide rotation mechanism that rotates each lower guide about the lower rotary shaft to make the first lower contact region and the second lower contact region selectively serve as the downward inclined plane, and an upper guide rotation mechanism that rotates each upper guide about the upper rotary shaft to make the first upper contact region and the second upper contact region selectively serve as the upward inclined plane.

Preferably, the lower guide rotation mechanism rotates each lower guide 180 degrees about the lower rotary shaft to make the first lower contact region and the second lower contact region selectively serve as the downward inclined plane. The upper guide rotation mechanism rotates each upper guide 180 degrees about the upper rotary shaft to make the first upper contact region and the second upper contact region selectively serve as the upward inclined plane.

Preferably, each upper guide is disposed at a position different from a position of each lower guide in plan view.

The present invention is also intended for a substrate processing apparatus. A substrate processing apparatus according to a preferable embodiment of the present invention includes the substrate inverting device described above, a back-surface cleaning part that cleans a back surface of the substrate inverted by the substrate inverting device, and a substrate transporter that transports the substrate between the substrate inverting device and the back-surface cleaning part.

Preferably, the substrate processing apparatus further includes a cleaning processing block in which the back-surface cleaning part and the substrate transporter are disposed, and an indexer block in which another substrate transporter is disposed and that passes an unprocessed substrate to the cleaning processing block and receives a processed substrate from the cleaning processing block. The substrate inverting device is disposed at a connection between the cleaning processing block and the indexer block. In a case where one transporter out of the substrate transporter and the other substrate transporter transports a substrate into the substrate inverting device, the substrate inverted by the substrate inverting device is transported out of the substrate inverting device by the other substrate transporter.

The present invention is also intended for a substrate catch-and-hold device. A substrate catch-and-hold device according to a preferable embodiment of the present invention includes a plurality of lower guides each having a downward inclined plane that is inclined downward toward an inner side in a width direction of a substrate and that comes in contact with a peripheral edge portion of the substrate held in a horizontal position to support the substrate from below, a plurality of upper guides each having an upward inclined plane that is inclined upward toward the inner side in the width direction and that comes in contact with the peripheral edge portion of the substrate at a position above a position of contact between the substrate and the plurality of lower guides to catch and hold the substrate between the plurality of lower guides and the plurality of upper guides, and a switching mechanism that changes states of contact between the plurality of lower guides and the substrate and between the plurality of upper guides and the substrate. Each lower guide includes a first lower contact region and a second lower contact region that are switched by the switching mechanism and selectively serve as the downward inclined plane. Each upper guide includes a first upper contact region and a second upper contact region that are switched by the switching mechanism and selectively serve as the upward inclined plane.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a plan view of a substrate processing apparatus according to an embodiment;

FIG. 2 is a view of the substrate processing apparatus taken along line II-II;

FIG. 3 is a view of the substrate processing apparatus taken along line III-III;

FIG. 4 is a front view of an inversion unit;

FIG. 5 is a plan view of the inversion unit;

FIG. 6 is a view of the inversion unit taken along line VI-VI;

FIG. 7 is an enlarged view of an upper guide and a lower guide;

FIG. 8 is an enlarged view of the upper guide and the lower guide;

FIG. 9 shows an example of operations performed in the case of inverting a substrate;

FIG. 10 shows an example of operations performed in the case of inverting a substrate;

FIG. 11 shows an example of operations performed in the case of inverting a substrate;

FIG. 12 shows an example of operations performed in the case of inverting a substrate;

FIG. 13 shows an example of operations performed in the case of inverting a substrate;

FIG. 14 shows an example of operations performed in the case of inverting a substrate;

FIG. 15 shows an example of operations performed in the case of inverting a substrate;

FIG. 16 shows an example of operations performed in the case of inverting a substrate;

FIG. 17 is a plan view illustrating another arrangement of upper guides and lower guides;

FIG. 18 illustrates an upper guide and a lower guide of another substrate inverting device;

FIG. 19 illustrates the upper guide and the lower guide of the other substrate inverting device;

FIG. 20 is a plan view of another substrate processing apparatus; and

FIG. 21 is a view of the substrate processing apparatus taken along line XXI-XXI.

### DESCRIPTION OF EMBODIMENTS

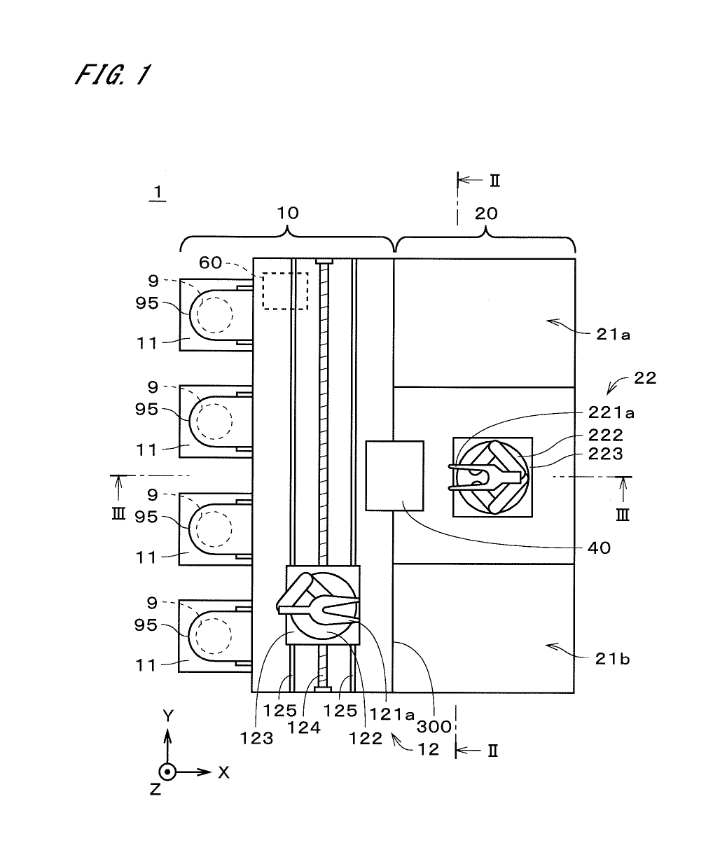

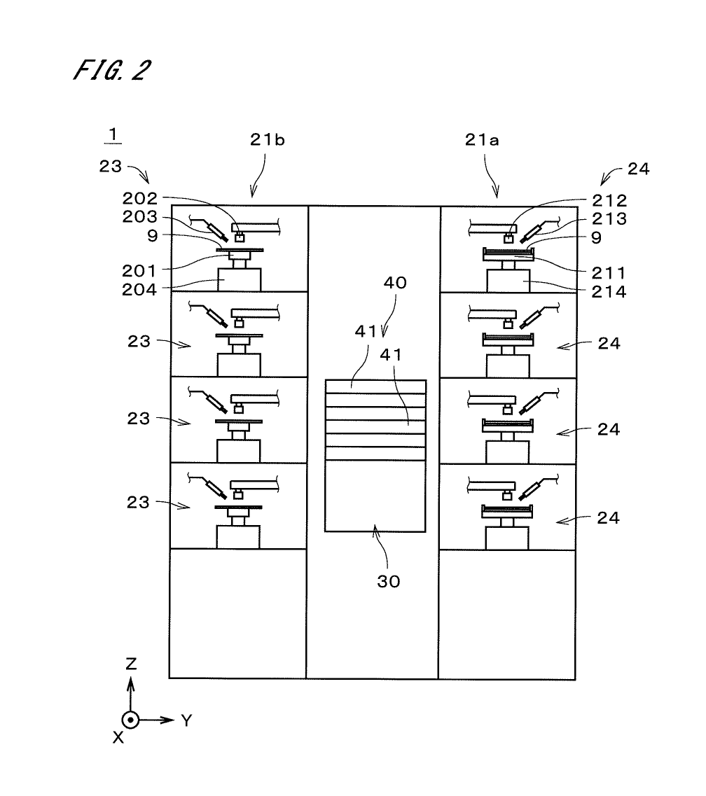

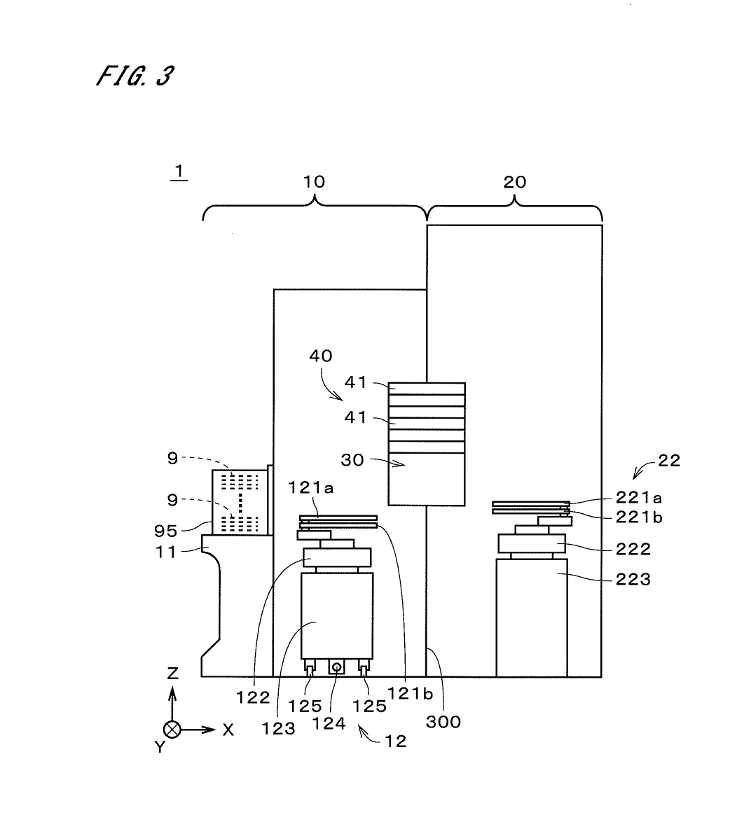

FIG. 1 is a plan view of a substrate processing apparatus 1 according to an embodiment of the present invention. FIG. 2 is a view of the substrate processing apparatus 1 taken along line II-II in FIG. 1. FIG. 3 is a view of the substrate processing apparatus 1 taken along line III-III in FIG. 1. Note that an XYZ orthogonal coordinate system in which the Z axial direction is the vertical direction (i.e., up-down direction) and an XY plane is a horizontal plane is appropriately given to each drawing referenced below.

The substrate processing apparatus 1 is an apparatus that continuously performs processing on a plurality of semiconductor substrates 9 (hereinafter, simply referred to as “substrates 9”). The substrate processing apparatus 1 performs, for example, cleaning processing on substrates 9. The substrate processing apparatus 1 includes an indexer block 10 and a cleaning processing block 20. In the following description, the indexer block 10 and the cleaning processing block 20 are respectively referred to as an indexer cell 10 and a cleaning processing cell 20. The indexer cell 10 and the cleaning processing cell 20 are arranged adjacent to each other in the X direction.

The substrate processing apparatus 1 further includes an inversion unit 30, a placement unit 40, and a controller 60. The inversion unit 30 and the placement unit 40 are disposed at a connection between the indexer cell 10 and the cleaning processing cell 20. Specifically, the inversion unit 30 and the placement unit 40 are provided through part of a partition wall 300 that is provided for interrupting atmospheres between the indexer cell 10 and the cleaning processing cell 20. The controller 60 controls each operating mechanism such as the indexer cell 10, the cleaning processing cell 20, and the inversion unit 30 and causes the operating mechanisms to execute cleaning processing of substrates 9. The controller 60 is, for example, a typical computer system that includes, for example, a CPU that performs various types of arithmetic processing, a ROM that stores basic programs, and a RAM that stores various types of information.

The indexer cell 10 receives substrates 9 transported from outside the substrate processing apparatus 1 (i.e., unprocessed substrates before being subjected to processing performed by the cleaning processing cell 20) and passes the substrates 9 to the cleaning processing cell 20. The indexer cell 10 also receives substrates 9 transported out of the cleaning processing cell 20 (i.e., processed substrates that have undergone the processing performed by the cleaning processing cell 20) and transports the substrates 9 out of the substrate processing apparatus 1. The indexer cell 10 includes a plurality of (e.g., four) carrier stages 11 and a transfer robot 12. Each carrier stage 11 has placed thereon a carrier 95 that can house a plurality of disc-like substrates 9. The transfer robot 12 serves as a substrate transporter that takes unprocessed substrates 9 out of each carrier 95 and houses processed substrates 9 in each carrier 95.

Referring to each carrier stage 11, a carrier 95 that houses a plurality of unprocessed substrates 9 is transported from outside into the substrate processing apparatus 1 and placed on the carrier stage 11 by, for example, an automatic guided vehicle (AGV). Processed substrates 9 that have undergone the cleaning processing performed by the cleaning processing cell 20 are housed again in the carrier 95 placed on the carrier stage 11. The carrier 95 in which the processed substrates 9 are housed is transported out of the substrate processing apparatus 1 by, for example, an AGV. That is, the carrier stage 11 functions as a substrate accumulation part that accumulates unprocessed substrates 9 and processed substrates 9. The carrier 95 is, for example, a front opening unified pod (FOUP) that houses substrates 9 in an enclosed space. The carrier 95 is not limited to the FOUP, and may, for example, be a standard mechanical interface (SMIF) pod, or an open cassette (OC) that exposes housed substrates 9 to outside air.

The transfer robot 12 includes two transport arms 121a and 121b, an arm stage 122, and a movable mount 123. The two transport arms 121a and 121b are mounted on the arm stage 122. The movable mount 123 has threaded engagement with a ball screw 124 that extends in parallel with the direction of arrangement of the plurality of carrier stages 11 (i.e., in the Y direction) and is provided slidably along two guide rails 125. When the ball screw 124 is rotated by a rotary motor (not shown), the transfer robot 12 in its entirety including the movable mount 123 is moved horizontally in the Y direction.

The arm stage 122 is mounted on the movable mount 123. The movable mount 123 includes a built-in motor (not shown) that rotates the arm stage 122 about a rotation axis extending in the up-down direction (i.e., Z direction) and a built-in motor (not shown) that moves the arm stage 122 in the up-down direction. The transport arms 121a and 121b are disposed away from each other in the up-down direction on the arm stage 122. The transport arms 121a and 121b each have a forked shape in plan view. Each of the transport arms 121a and 121b supports the lower surface of one substrate 9 with its forked portion. Also, the articulated structures of the transport arms 121a and 121b are expanded and contracted by a drive mechanism (not shown) built in the arm stage 122, so that the transport arms 121a and 121b are moved independently of each other in the horizontal direction (i.e., a radial direction about the rotation axis of the arm stage 122).

The transfer robot 12 transports substrates 9 among the carriers 95, the inversion unit 30, and the placement unit 40 by causing each of the transport arms 121a and 121b that support the substrates 9 with their forked portions to individually access the carriers 95 placed on the carrier stages 11, the inversion unit 30, and the placement unit 40.

The cleaning processing cell 20 is, for example, a cell (i.e., processing block) that performs scrub cleaning processing on substrates 9. The cleaning processing cell 20 includes two cleaning processing units 21a and 21b and a transport robot 22. The transport robot 22 serves as a substrate transporter that receives and passes substrates 9 from and to the inversion unit 30, the placement unit 40, and the cleaning processing units 21a and 21b.

The cleaning processing units 21a and 21b face each other in the Y direction with the transport robot 22 sandwiched therebetween. The cleaning processing unit 21b on the −Y side of the transport robot 22 includes one or more front-surface cleaning processing parts 23. The cleaning processing unit 21b illustrated in FIG. 2 includes four front-surface cleaning processing parts 23 that are stacked one above another in the up-down direction. The cleaning processing unit 21a on the +Y side of the transport robot 22 includes one or more back-surface cleaning processing parts 24. The cleaning processing unit 21a illustrated in FIG. 2 includes four back-surface cleaning processing parts 24 that are stacked one above another in the up-down direction.

The front-surface cleaning processing parts 23 perform scrub cleaning processing on the front surfaces of substrates 9. The “front surface” of a substrate 9 as used herein refers to one main surface on which a pattern (e.g., circuit pattern) is formed, out of the two main surfaces of the substrate 9. The “back surface” of a substrate 9 as used herein refers to the opposite main surface of the front surface of the substrate 9. The front-surface cleaning processing parts 23 each include, for example, a spin chuck 201, a cleaning brush 202, a nozzle 203, and a spin motor 204. The spin chuck 201 holds a substrate 9 in a horizontal position with the front surface facing upward, and rotates the substrate 9 about a rotation axis extending in the up-down direction. The spin chuck 201 holds a substrate 9 by, for example, adsorbing the back surface of the substrate 9. The cleaning brush 202 comes in contact with or in close proximity to the front surface of the substrate 9 held on the spin chuck 201 and performs scrub cleaning on the front surface of the substrate 9. The nozzle 203 ejects a cleaning liquid (e.g., deionized water) to the front surface of the substrate 9. The spin motor 204 rotates the substrate 9 together with the spin chuck 201. The cleaning liquid dispersed from the rotating substrate 9 to the surroundings is received by a cup part (not shown) that surrounds the substrate 9.

The back-surface cleaning processing parts 24 perform scrub cleaning processing on the back surfaces of substrates 9. The back-surface cleaning processing parts 24 each include, for example, a spin chuck 211, a cleaning brush 212, a nozzle 213, and a spin motor 214. The spin chuck 211 holds a substrate 9 in a horizontal position with the back surface facing upward, and rotates the substrate 9 about a rotation axis extending in the up-down direction. The spin chuck 211 holds the substrate 9 by, for example, mechanically catching and holding the edge portion of the substrate 9. The cleaning brush 212 comes in contact with or in close proximity to the back surface of the substrate 9 held on the spin chuck 211 and performs scrub cleaning on the back surface of the substrate 9. The nozzle 213 ejects a cleaning liquid (e.g., deionized water) to the back surface of the substrate 9. The spin motor 214 rotates the substrate 9 together with the spin chuck 211. The cleaning liquid dispersed from the rotating substrate 9 to the surroundings is received by a cup part (not shown) that surrounds the substrate 9.

The transport robot 22 includes two transport arms 221a and 221b, an arm stage 222, and a mount 223. The two transport arms 221a and 221b are mounted on the arm stage 222. The mount 223 is fixed to the frame of the cleaning processing cell 20. Thus, the mount 223 of the transport robot 22 does not move in the horizontal direction and the up-down direction.

The arm stage 222 is mounted on the mount 223. The mount 223 includes a built-in motor (not shown) that rotates the arm stage 222 about a rotation axis extending in the up-down direction, and a built-in motor (not shown) that moves the arm stage 222 in the up-down direction. The transport arms 221a and 221b are disposed away from each other in the up-down direction on the arm stage 222. The transport arms 221a and 221b each have a forked shape in plan view. Each of the transport arms 221a and 221b supports the lower surface of one substrate 9 with its forked portion. Also, the articulated structure of each transport arm 221a or 221b is expanded and contracted by a drive mechanism (not shown) built in the arm stage 222, so that the transport arms 221a and 221b are moved independently of each other in the horizontal direction (i.e., a radial direction about the rotation axis of the arm stage 222).

The transport robot 22 transports substrates 9 among the cleaning processing units 21a and 21b, the inversion unit 30, and the placement unit 40 by causing each of the transport arms 221a and 221b that support the substrates 9 with their forked portions to access the cleaning processing units 21a and 21b, the inversion unit 30, and the placement unit 40. Note that other mechanisms such as a belt feed mechanism using a pulley and a timing belt may be employed as the up-down movement mechanism of the transport robot 22.

The inversion unit 30 inverts unprocessed substrates 9 received from the indexer cell 10 upside down (i.e., inverts the front and back surfaces of unprocessed substrates 9 by 180 degrees) and then passes the unprocessed substrates 9 to the cleaning processing cell 20. The inversion unit 30 inverts processed substrates 9 received from the cleaning processing cell 20 upside down (i.e., inverts the front and back surfaces of processed substrates 9 by 180 degrees) and then passes the processed substrates 9 to the indexer cell 10 or the cleaning processing cell 20. That is, the inversion unit 30 has both a function as an inversion part that inverts substrates 9 and a function as a part that receives and passes substrates 9 between the transfer robot 12 and the transport robot 22. The structure of the inversion unit 30 will be described later.

The placement unit 40 is disposed above the inversion unit 30. The placement unit 40 and the inversion unit 30 may be in contact with each other in the up-down direction or may be spaced from each other in the up-down direction. The placement unit 40 is used to receive and pass substrates 9 between the indexer cell 10 and the cleaning processing cell 20. The placement unit 40 includes one or more placement parts 41. The placement unit 40 illustrated in FIGS. 2 and 3 includes six placement parts 41 that are stacked one above another in the up-down direction. Each placement part 41 supports one substrate 9 in a horizontal position. In the placement unit 40, for example, the upper three placement parts 41 among the six placement parts 41 are used to receive and pass processed substrates 9 from the cleaning processing cell 20 to the indexer cell 10, and the lower three placement parts 41 are used to receive and pass unprocessed substrates 9 from, for example, the indexer cell 10 to the cleaning processing cell 20.

Next, one example of the flow of processing performed on substrates 9 by the substrate processing apparatus 1 will be described. The substrate processing apparatus 1 performs processing on substrates 9 in accordance with a procedure (so-called flow) for transporting substrates 9 and a recipe that describes processing conditions for substrates 9. The following is a description of a case where the both surfaces (i.e., front and back surfaces) of substrates 9 are cleaned.

First, a carrier 95 that houses unprocessed substrates 9 is transported from outside the substrate processing apparatus 1 into a carrier stage 11 of the indexer cell 10 by, for example, an AGV. Then, the transfer robot 12 of the indexer cell 10 takes two unprocessed substrates 9 out of the carrier 95 and transports the two substrates 9 into the inversion unit 30 by using the transport arms 121a and 121 b. The substrates 9 are transported into the inversion unit 30, with their front surfaces facing upward. In the inversion unit 30, a substrate inverting device 100 inverts the front and back of the two substrates 9 so that the back surface of each substrate 9 faces upward. The operations of the substrate inverting device 100 will be described later.

When the two substrates 9 have been inverted by the inversion unit 30, the transport robot 22 of the cleaning processing cell 20 receives the two substrates 9 (i.e., two substrates 9 with their back surfaces facing upward) from the inversion unit 30 by using the transport arms 221a and 221b. The transport robot 22 transports the two substrates 9 respectively to arbitrary two back-surface cleaning processing parts 24 among the four back-surface cleaning processing parts 24.

The back-surface cleaning processing parts 24 in which the substrates 9 have been transported perform back-surface cleaning processing on the substrates 9. Specifically, in the back-surface cleaning processing parts 24, a cleaning liquid is supplied from the nozzle 213 to the back surface of the substrate 9 while the substrate 9 with its back surface facing upward is held and being rotated by the spin chuck 211. In this state, the cleaning brush 212 comes in contact with or in close proximity to the back surface of the substrate 9 and scans the substrate 9 in the horizontal direction, so that scrub cleaning processing is performed on the back surface of the substrate 9.

When the back-surface cleaning processing parts 24 have finished the back-surface cleaning processing of the substrates 9, the transport robot 22 successively takes the two substrates 9 that have undergone the back-surface cleaning processing, out of the two back-surface cleaning processing parts 24 and transports the two substrates 9 into the inversion unit 30 by using the transport arms 221a and 221b. The substrates 9 are transported into the inversion unit 30, with their back surfaces facing upward. In the inversion unit 30, the substrate inverting device 100 inverts the front and back of the two substrates 9 so that each substrate 9 has its front surface facing upward.

When the two substrates 9 have been inverted by the inversion unit 30, the transport robot 22 of the cleaning processing cell 20 receives the two substrates 9 (i.e., two substrates 9 with their front surfaces facing upward) from the inversion unit 30 by using the transport arms 221a and 221b. The transport robot 22 transports the two substrates 9 respectively to arbitrary two front-surface cleaning processing parts 23 among the four front-surface cleaning processing parts 23.

The front-surface cleaning processing parts 23 in which the substrates 9 have been transported perform front-surface cleaning processing on the substrates 9. Specifically, in the front-surface cleaning processing parts 23, a cleaning liquid is supplied from the nozzle 203 to the front surface of the substrate 9 while the substrate 9 with its front surface facing upward is held and being rotated by the spin chuck 201. In this state, the cleaning brush 202 comes in contact with or in close proximity to the front surface of the substrate 9 and scans the substrate 9 in the horizontal direction, so that scrub cleaning processing is performed on the front surface of the substrate 9.

When the front-surface cleaning processing parts 23 have finished the front-surface cleaning processing of the substrates 9, the transport robot 22 successively takes the two substrates 9 (i.e., processed substrates 9) that have undergone the front-surface cleaning processing, out of the two front-surface cleaning processing parts 23 and transports the two substrates 9 into two placement parts 41 of the placement unit 40 by using the transport arms 221a and 221b. The substrates 9 are supported by the placement parts 41, with their front surfaces facing upward. Then, the transfer robot 12 of the indexer cell 10 takes out the two processed substrates 9 and houses the substrates 9 in the carrier 95 by using the transport arms 121a and 121b.

As described above, in the substrate processing apparatus 1, the substrate inverting device 100 can invert the front and back of substrates 9 when the substrates 9 are received and passed between the transfer robot 12 provided in the indexer cell 10 and the transport robot 22 provided in the cleaning processing cell 20. That is, the substrate inverting device 100 has not only a function of inverting substrates 9 but also a function as a part that receives and passes substrates 9 between the transfer robot 12 and the transport robot 22. This configuration reduces loads on the transport robot 22 and reduces the number of processing steps to be performed in the cleaning processing cell 20, as compared with the case where the part that receives and passes substrates 9 and the inversion part are provided separately. As a result, it is possible to efficiently suppress a reduction in the throughput of the substrate processing apparatus 1. Also, the substrate inverting device 100 of the inversion unit 30 can properly invert two substrates 9 at one time, as will be described later. This further improves the throughput of the substrate processing apparatus 1.

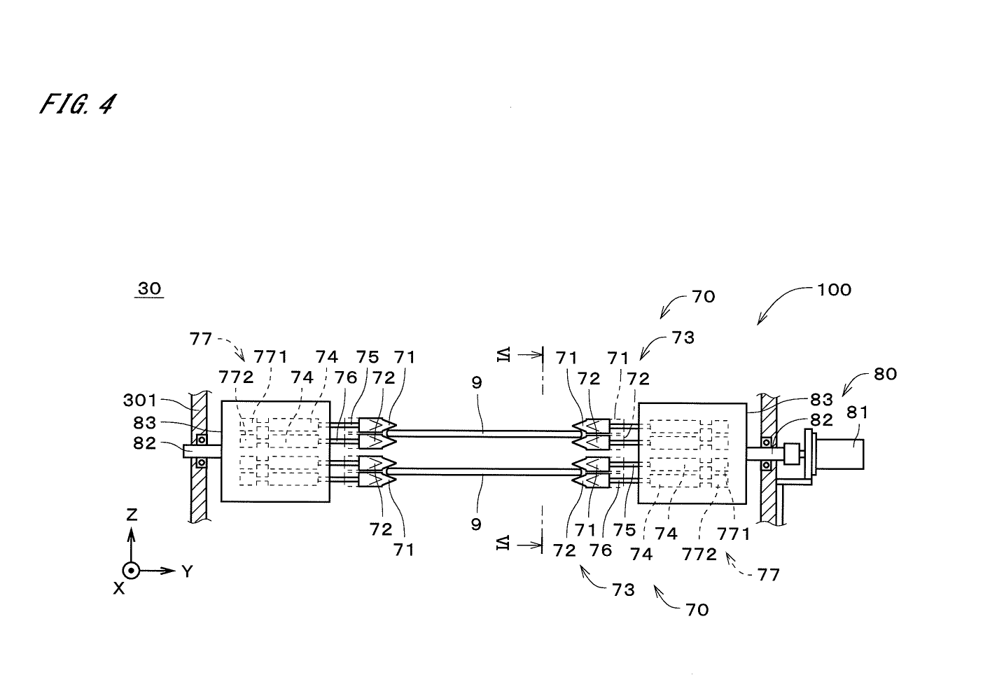

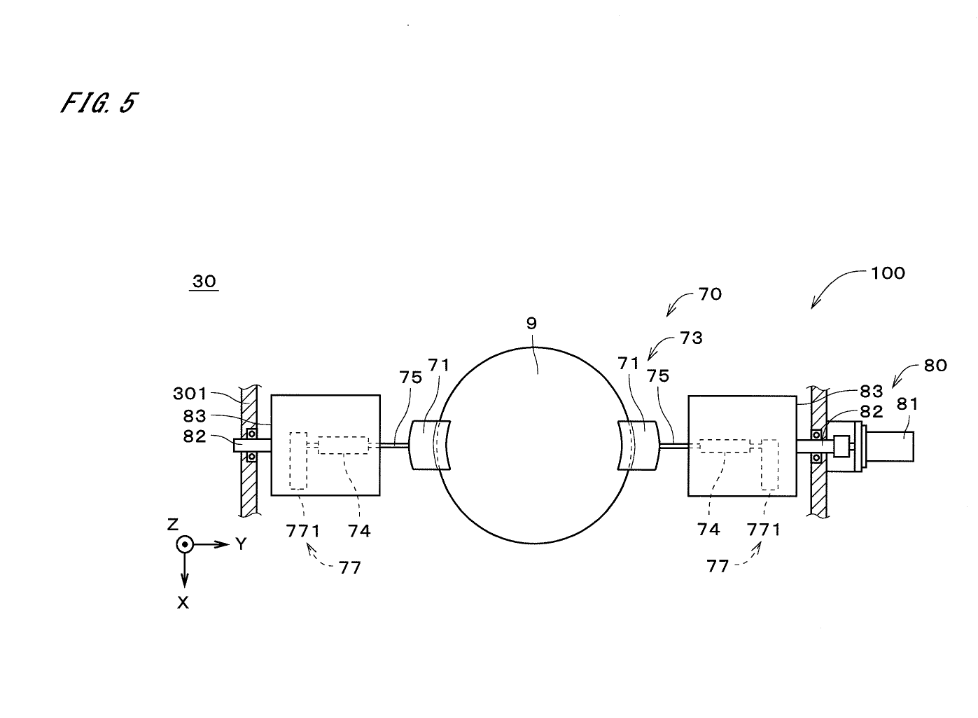

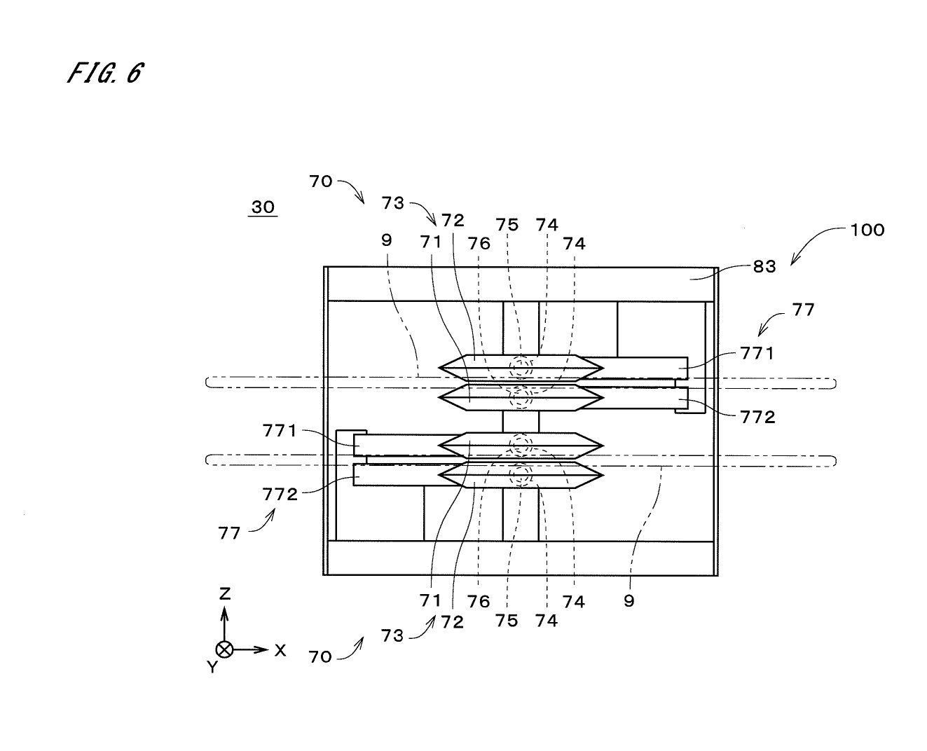

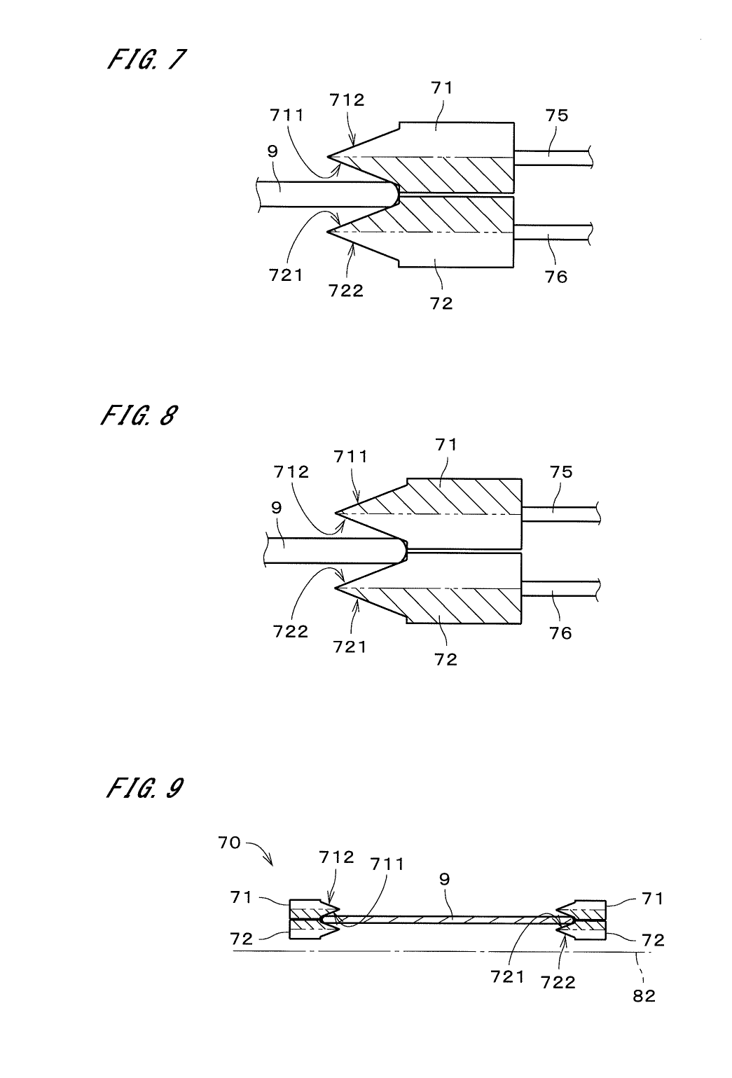

Next, the configuration of the inversion unit 30 will be described with reference to FIGS. 4 to 7. FIG. 4 is a front view of the inversion unit 30 when viewed from the +X side. FIG. 5 is a plan view of the inversion unit 30. FIG. 6 is a view of the inversion unit 30 taken along line VI-VI in FIG. 4. FIGS. 7 and 8 show one example of an upper guide 71 and a lower guide 72, which will be described later.

The inversion unit 30 includes the substrate inverting device 100 and a casing 301. The casing 301 houses the substrate inverting device 100 therein. The substrate inverting device 100 includes two catch-and-hold mechanisms 70 and an inversion mechanism 80. Each catch-and-hold mechanism 70 comes in contact with the peripheral edge portion of a substrate 9 held in a horizontal position and catches and holds the substrate 9. The two catch-and-hold mechanisms 70 have approximately the same structure. Two substrates 9 that are caught and held by the two catch-and-hold mechanisms 70 are stacked one above another with an interval therebetween in the up-down direction. The inversion mechanism 80 inverts the two substrates 9 caught and held by the two catch-and-hold mechanisms 70 at one time. Note that the substrate inverting device 100 may include one or three or more catch-and-hold mechanisms 70.

The transfer robot 12 and the transport robot 22 (see FIG. 1) can access the inside of the casing 301. Out of the wall of the casing 301, a wall portion on the side close to the cleaning processing cell 20 (i.e., +X side) has an opening 302 for allowing the transport arms 221a and 221b of the transport robot 22 to access the inside of the casing 301. Also, out of the wall of the casing 301, a wall portion on the side close to the indexer cell 10 (i.e., −X side) has an opening for allowing the transport arms 121a and 121b of the transfer robot 12 to access the inside of the casing 301. In the following description, the +X side where the opening of the casing 301 is present is referred to as the “front side,” and the −X side where another opening is present is referred to as the “back side.” Also, the Y direction that is orthogonal to the back-and-forth direction (i.e., X direction) and the up-down direction (i.e., Z direction) is referred to as a “right-left direction.” The right-left direction is also the width direction of the substrate inverting device 100.

As illustrated in FIGS. 4 to 6, each catch-and-hold mechanism 70 includes a guide part 73, a guide moving mechanism 74, and a switching mechanism 77. The guide part 73 includes two upper guides 71 and two lower guides 72. The two upper guides 71 are located on an extension of the diameter of a substrate 9 that extends in the right-left direction. In other words, the two upper guides 71 face each other in the right-left direction, with the center of a substrate 9 sandwiched therebetween. The two lower guides 72 are respectively located vertically below the two upper guides 71. In other words, the upper guide 71 and the lower guide 72 in one set that are aligned in the up-down direction are located at the same circumferential position about a central axis that extends in the up-down direction through the center of the substrate 9. The upper guide 71 and the lower guide 72 in one set located on the +Y side of the substrate 9 catch and hold the peripheral edge portion of the substrate 9 on the +Y side. Also, the upper guide 71 and the lower guide 72 in the other one set located on the −Y side of the substrate 9 catch and hold the peripheral edge portion of the substrate 9 on the −Y side. Note that the number of upper guides 71 and the number of lower guides 72, included in the guide part 73, may each be appropriately changed as long as there are a plurality of upper guides 71 and a plurality of lower guides 72.

Each upper guide 71 is fixed to the tip end of an upper rotary shaft 75 of a generally columnar shape extending in the Y direction, and is supported by the upper rotary shaft 75. Each lower guide 72 is fixed to the tip end of a lower rotary shaft 76 of a generally columnar shape extending in the Y direction, and is supported by the lower rotary shaft 76. The guide moving mechanism 74 is attached to each upper rotary shaft 75 and each lower rotary shaft 76 and moves each upper rotary shaft 75 and each lower rotary shaft 76 in the Y direction. Accordingly, the plurality of upper guides 71 and the plurality of lower guides 72 move in the Y direction. Each upper guide 71 and each lower guide 72 are movable independently of each other.

The guide moving mechanism 74 advances and retracts the plurality of upper guides 71 and the plurality of lower guides 72 between contact positions at which the guides come in contact with substrates 9 and retracted positions that are further away from substrates 9 on the radially outer side (i.e., outward in the width direction of the substrates 9) than the contact positions. In FIG. 4, the contact positions of each upper guide 71 and each lower guide 72 are indicated by solid lines, and the retracted positions thereof are indicated by dashed double-dotted lines. The guide moving mechanism 74 is, for example, an air cylinder.

The switching mechanism 77 includes a plurality of upper guide rotation mechanisms 771 and a plurality of lower guide rotation mechanisms 772. Each upper guide rotation mechanism 771 is attached to one of the upper rotary shafts 75 and rotates the upper rotary shaft 75 about the central axis of the upper rotary shaft 75. Each lower guide rotation mechanism 772 is attached to one of the lower rotary shafts 76 and rotates the lower rotary shaft 76 about the central axis of the lower rotary shaft 76. Accordingly, each upper guide 71 rotates about the upper rotary shaft 75 extending in the width direction (i.e., Y direction). Also, each lower guide 72 rotates about the lower rotary shaft 76 extending in the width direction. Each upper guide 71 and each lower guide 72 are rotatable independently of each other. In the example illustrated in FIG. 4, each upper guide 71 can rotate 180 degrees about the upper rotary shaft 75. Also, each lower guide 72 can rotate 180 degrees about the lower rotary shaft 76. The upper guide rotation mechanisms 771 and the lower guide rotation mechanisms 772 are, for example, electric motors.

As illustrated in FIG. 7, each upper guide 71 includes a first upper contact region 711 and a second upper contact region 712. In the state illustrated in FIG. 7, the first upper contact region 711 is an inclined plane that is inclined upward toward the radially inner side (i.e., the inner side in the width direction of a substrate 9). The second upper contact region 712 is located vertically above the first upper contact region 711. The second upper contact region 712 is an inclined plane that is inclined downward toward the inner side in the width direction. The first upper contact region 711 and the second upper contact region 712 are each an approximately flat plane without unevenness. Alternatively, the first upper contact region 711 and the second upper contact region 712 may each be a concave plane or a convex plane.

The first upper contact region 711 and the second upper contact region 712 have approximately the same shape, except that they are turned upside down. Also, the first upper contact region 711 and the second upper contact region 712 are disposed at approximately the same position in the width direction (i.e., the longitudinal direction of the upper rotary shaft 75). In other words, the first upper contact region 711 and the second upper contact region 712 have plane symmetry with respect to a virtual horizontal plane positioned at the center of the first upper contact region 711 and the second upper contact region 712 in the up-down direction.

The lower guides 72 have approximately the same shape as the upper guides 71. Each lower guide 72 includes a first lower contact region 721 and a second lower contact region 722. In the state illustrated in FIG. 7, the first lower contact region 721 is an inclined plane that is inclined downward toward the inner side in the width direction. The second lower contact region 722 is located vertically below the first lower contact region 721. The second lower contact region 722 is an inclined plane that is inclined upward toward the inner side in the width direction. The first lower contact region 721 and the second lower contact region 722 are each an approximately flat plane without unevenness. The first lower contact region 721 and the second lower contact region 722 may each be a concave plane or a convex plane.

The first lower contact region 721 and the second lower contact region 722 have approximately the same shape, except that they are turned upside down. Also, the first lower contact region 721 and the second lower contact region 722 are located at approximately the same position in the width direction (i.e., the longitudinal direction of the lower rotary shaft 76). In other words, the first lower contact region 721 and the second lower contact region 722 have plane symmetry with respect to a virtual horizontal plane positioned at the center of the first lower contact region 721 and the second lower contact region 722 in the up-down direction.

In the state illustrated in FIG. 7, the first upper contact region 711 of the upper guide 71 and the first lower contact region 721 of the lower guide 72 face each other in the up-down direction and come in contact with the peripheral edge portion of a substrate 9. That is, the first upper contact region 711 serves as an upper contact surface of the upper guide 71 that comes in contact with the peripheral edge portion of the substrate 9. The upper contact surface is inclined upward toward the inner side in the width direction of the substrate 9. The first lower contact region 721 serves as a lower contact surface of the lower guide 72 that comes in contact with the peripheral edge portion of the substrate 9. The lower contact surface is inclined downward toward the inner side in the width direction of the substrate 9. The lower contact surface comes in contact with the peripheral edge portion of the substrate 9 held in a horizontal position and supports the substrate 9 from below. The upper contact surface comes in contact with the peripheral edge portion of the substrate 9 held in a horizontal position at a position above the position of contact between the lower contact surface and the substrate 9.

In FIGS. 7 and 8, a portion where the first upper contact region 711 is provided out of the upper and lower halves of the upper guide 71 and a portion where the first lower contact region 721 is provided out of the upper and lower halves of the lower guide 72 are indicated by diagonal parallel lines.

In the catch-and-hold mechanisms 70, the upper guide rotation mechanisms 771 (see FIG. 4) of the switching mechanism 77 rotate the upper guides 71 by 180 degrees about the upper rotary shafts 75 so as to switch the positions of the first upper contact regions 711 and the second upper contact regions 712. In other words, the upper guide rotation mechanisms 771 invert the upper guides 71 upside down. Accordingly, as illustrated in FIG. 8, the second upper contact region 712 of each upper guide 71 is positioned vertically below the first upper contact region 711 thereof. In the state illustrated in FIG. 8, the second upper contact region 712 serves as the upper contact surface that is inclined upward toward the inner side in the width direction of the substrate 9 and comes in contact with the peripheral edge portion of the substrate 9. The first upper contact region 711 is inclined downward toward the inner side in the width direction of the substrate 9.

Also, the lower guide rotation mechanisms 772 (see FIG. 4) of the switching mechanism 77 rotate the lower guides 72 by 180 degrees about the lower rotary shafts 76 so as to switch the positions of the first lower contact regions 721 and the second lower contact regions 722. In other words, the lower guide rotation mechanisms 772 invert the lower guides 72 upside down. Accordingly, as illustrated in FIG. 8, the second lower contact region 722 of each lower guide 72 is positioned vertically above the first lower contact regions 721 thereof. In the state illustrated in FIG. 8, the second lower contact region 722 serves as the lower contact surface that is inclined downward toward the inner side in the width direction of the substrate 9 and comes in contact with the peripheral edge portion of the substrate 9. The first lower contact region 721 is inclined upward toward the inner side in the width direction of the substrate 9.

In this way, in the catch-and-hold mechanism 70, the upper guide rotation mechanisms 771 of the switching mechanism 77 make the first upper contact regions 711 and the second upper contact regions 712 of the upper guides 71 selectively serve as the upper contact surfaces. Also, the lower guide rotation mechanisms 772 of the switching mechanism 77 make the first lower contact regions 721 and the second lower contact regions 722 of the lower guides 72 selectively serve as the lower contact surfaces. That is, the switching mechanism 77 changes the states of contact between each upper guide 71 and the substrate 9 and between each lower guide 72 and the substrate 9.

As illustrated in FIGS. 4 and 5, the inversion mechanism 80 includes a drive part 81, two rotary shafts 82, and two housing parts 83. The two housing parts 83 are respectively disposed on the +Y and −Y sides of substrates 9. Each housing part 83 houses the guide moving mechanism 74, the upper guide rotation mechanisms 771, and the lower guide rotation mechanisms 772. The guide moving mechanism 74, the upper guide rotation mechanisms 771, and the lower guide rotation mechanisms 772 are fixed to the housing parts 83. Each rotary shaft 82 is a generally columnar member that extends outward in the width direction from one of the housing parts 83. Each rotary shaft 82 is rotatably supported by the casing 301.

The drive part 81 is attached to the rotary shaft 82 on the +Y side. When the drive part 81 rotates the rotary shaft 82 on the +Y side by 180 degrees, the housing part 83 on the +Y side, each catch-and-hold mechanism 70, the substrates 9 caught and held by the catch-and-hold mechanisms 70, the housing part 83 on the −Y side, and the rotary shaft 82 on the −Y side are rotated 180 degrees, and the substrates 9 are inverted upside down. In other words, the inversion mechanism 80 rotates the plurality of upper guides 71 and the plurality of lower guides 72 about the rotary shafts 82 pointing in the horizontal direction so as to invert the substrates 9 caught and held by the plurality of upper guides 71 and the plurality of lower guides 72. In the substrate inverting device 100, in the case where two substrates 9 are caught and held by the two catch-and-hold mechanisms 70, the two substrates 9 are inverted at the same time. In the case where only one of the catch-and-hold mechanisms 70 catches and holds a substrate 9, this substrate 9 is inverted alone.

In the substrate inverting device 100, when the substrates 9 have been inverted by the inversion mechanism 80, the upper guides 71 and the lower guides 72 are inverted upside down in the guide part 73 of each catch-and-hold mechanism 70. In other words, the upper guides 71 turn into the lower guides 72, and the lower guides 72 turn into the upper guides 71 with the inversion of the substrates 9.

FIGS. 9 to 16 illustrate an example of operations performed in the case of inverting substrates 9 in the substrate inverting device 100. The following description takes the example of operations performed in the case where unprocessed substrates 9 are transported into the substrate inverting device 100 and then inverted before being transported out of the substrate inverting device 100, and substrates 9 that have undergone cleaning processing are transported into the substrate inverting device 100 and then inverted. FIGS. 9 to 16 illustrate only some of the constituent elements of the substrate inverting device 100 such as a substrate 9, the upper guides 71, and the lower guides 72.

In FIGS. 9 to 16, portions where the first upper contact regions 711 are provided out of the upper and lower halves of the upper guides 71 and portions where the first lower contact regions 721 are provided out of the upper and lower halves of the lower guides 72 are indicated by diagonal parallel lines. Also, an unprocessed substrate 9 is indicated by diagonal parallel lines in FIGS. 9 to 16. Note that a processed substrate 9 is not given diagonal parallel lines. Moreover, the directions of movement of the upper guides 71 and the lower guides 72 and the direction of rotation produced by the inversion mechanism 80 are indicated by arrows. In FIGS. 9, 10, 15, and 16, the central axis of the rotary shafts 82 of the inversion mechanism 80 is indicated by a dashed dotted line. This dashed dotted line is indicated by reference numeral 82.

In FIG. 9, an unprocessed substrate 9 with its front surface facing upward is caught and held by the catch-and-hold mechanism 70. In the catch-and-hold mechanism 70, the upper guides 71 and the lower guides 72 are positioned at their contact positions. The first upper contact regions 711 of the upper guides 71 are in contact with the substrate 9. The first lower contact regions 721 of the lower guides 72 face the first upper contact regions 711 in the up-down direction and are in contact with the substrate 9. In other words, the first upper contact regions 711 and the first lower contact regions 721 respectively serve as upper contact surfaces and lower contact surfaces that come in contact with the substrate 9. The second upper contact regions 712 of the upper guides 71 and the second lower contact regions 722 of the lower guides 72 are not in contact with the substrate 9.

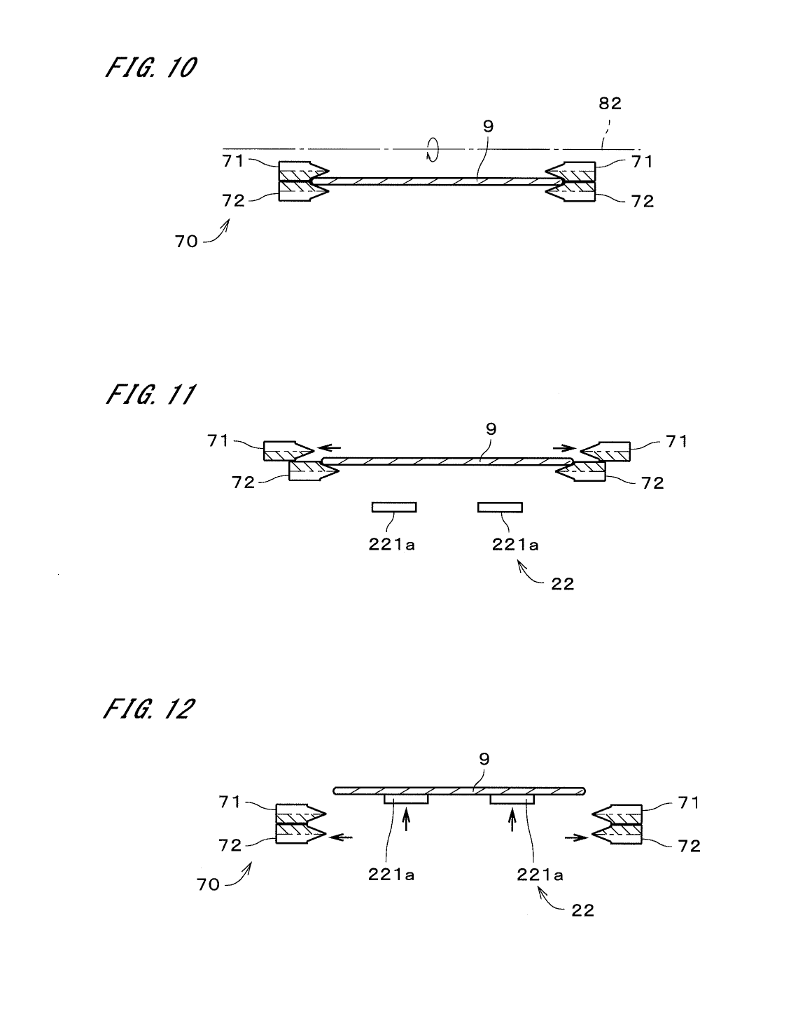

Then, as illustrated in FIG. 10, the substrate 9 and the catch-and-hold mechanism 70 are rotated about the rotary shafts 82 by the inversion mechanism 80 (see FIG. 4), so that the substrate 9 is inverted. The back surface of the substrate 9 faces upward. As described above, the upper guides 71 and the lower guides 72 in FIG. 9 respectively turn into the lower guides 72 and the upper guides 71 in FIG. 10 with the inversion of the substrate 9.

Next, as illustrated in FIG. 11, the two upper guides 71 are moved outward in the width direction by the guide moving mechanism 74 (see FIG. 4). Accordingly, the upper guides 71 are moved away from the substrate 9 and positioned at their retracted positions. The two lower guides 72 do not move from their contact positions and support the substrate 9 from below. Also, the transport arm 221a of the transport robot 22 of the cleaning processing cell 20 is disposed under the substrate 9.

Then, as illustrated in FIG. 12, the transport arm 221a moves upward and comes in contact with the lower surface of the substrate 9 to support the substrate 9 from below. Accordingly, the substrate 9 is passed from the catch-and-hold mechanism 70 to the transport robot 22. The transport robot 22 transports the unprocessed substrate 9 out of the substrate inverting device 100 and transports it into the cleaning processing cell 20 (see FIG. 1). The two lower guides 72 are moved outward in the width direction by the guide moving mechanism 74 and positioned at their retracted positions.

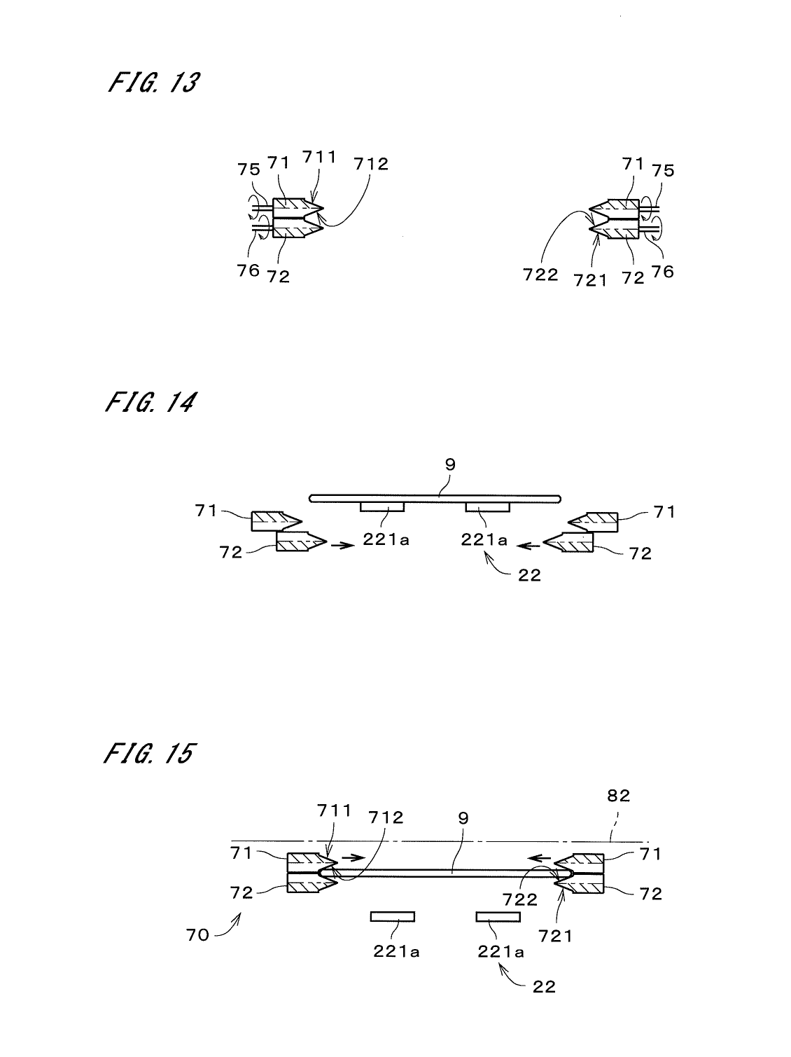

When the unprocessed substrate 9 has been transported out of the substrate inverting device 100, the upper guide rotation mechanisms 771 (see FIG. 4) of the switching mechanism 77 rotate the upper guides 71 by 180 degrees about the upper rotary shafts 75 as illustrated in FIG. 13. Accordingly, the second upper contact regions 712 are positioned vertically below the first upper contact regions 711. Also, the lower guide rotation mechanisms 772 (see FIG. 4) rotate the lower guides 72 by 180 degrees about the lower rotary shafts 76. Accordingly, the second lower contact regions 722 are positioned vertically above the first lower contact regions 721. The second lower contact regions 722 and the second upper contact regions 712 face each other in the up-down direction.

Next, as illustrated in FIG. 14, a processed substrate 9 supported from below by the transport arm 221a of the transport robot 22 is transported into the substrate inverting device 100. The substrate 9 with its back surface facing upward is supported by the transport arm 221a. The substrate 9 is positioned above the upper guides 71 and the lower guides 72. The two lower guides 72 are moved inward in the width direction by the guide moving mechanism 74 and positioned at their contact positions.

Next, as illustrated in FIG. 15, the transport arm 221a moves downward, and the second lower contact region 722 of each lower guide 72 comes in contact with the substrate 9 and supports the substrate 9 from below. The transport arm 221a is moved down away from the substrate 9. Accordingly, the substrate 9 is passed from the transport robot 22 to the catch-and-hold mechanism 70. Also, the two upper guides 71 are moved inward in the width direction by the guide moving mechanism 74 and positioned at their contact positions. The second upper contact region 712 of each upper guide 71 comes in contact with the substrate 9. Accordingly, the substrate 9 is caught and held by the upper guides 71 and the lower guides 72. Note that the first upper contact regions 711 of the upper guides 71 and the first lower contact regions 721 of the lower guides 72 are not in contact with the substrate 9.

In this way, in the substrate inverting device 100, the second upper contact regions 712 of the upper guides 71 and the second lower contact regions 722 of the lower guides 72, which do not come in contact with the unprocessed substrate 9, come in contact with the processed substrate 9. Also, the first upper contact regions 711 and the first lower contact regions 721 that come in contact with the unprocessed substrate 9 do not come in contact with the processed substrate 9. This configuration prevents grime, particles, or the like on the unprocessed substrate 9 from adhering to the processed substrate 9 via the regions of contact between the upper guides 71 and the substrate 9 and between the lower guides 72 and the substrate 9.

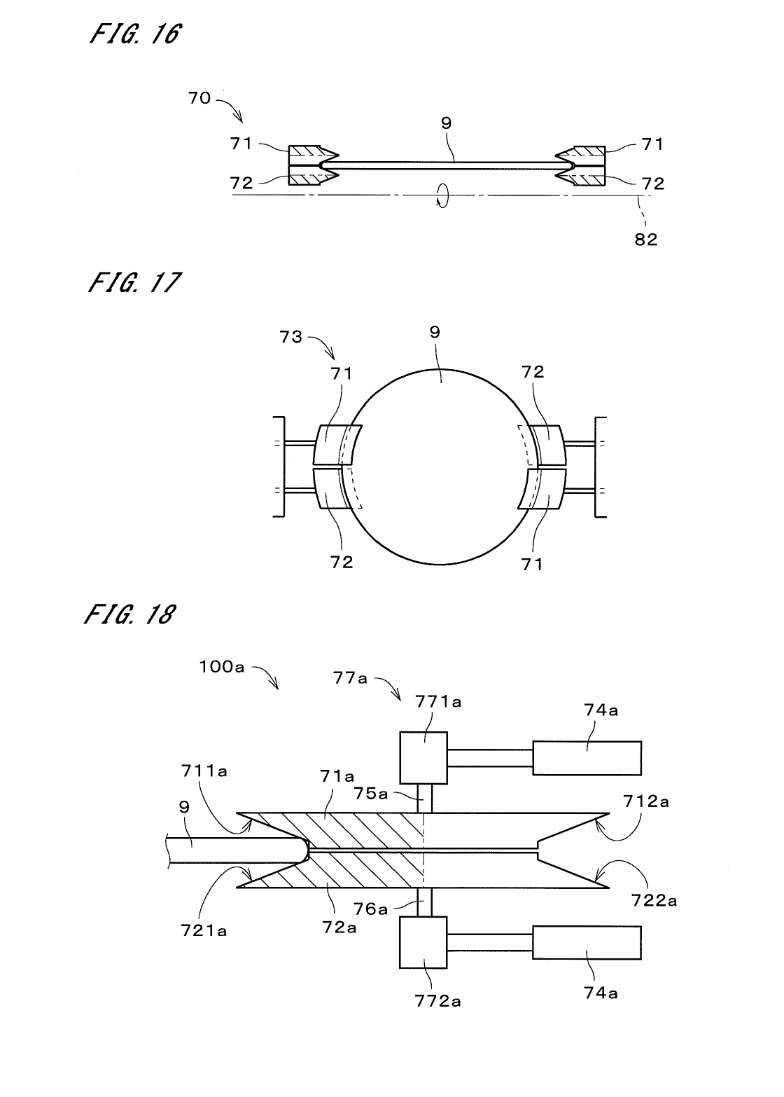

Thereafter, as illustrated in FIG. 16, the substrate 9 and the catch-and-hold mechanism 70 are rotated about the rotary shafts 82 by the inversion mechanism 80, so that the substrate 9 is inverted. The front surface of the substrate 9 faces upward. As described above, the upper guides 71 and the lower guides 72 in FIG. 15 respectively turn into the lower guides 72 and the upper guides 71 in FIG. 16 with the inversion of the substrate 9. The substrate 9 with its front surface facing upward is transported out of the substrate inverting device 100 and housed in a carrier 95 by the transport arm 121a (see FIG. 1) of the transfer robot 12 of the indexer cell 10.

As described above, the substrate inverting device 100 includes the plurality of upper guides 71, the plurality of lower guides 72, the inversion mechanism 80, the guide moving mechanism 74, and the switching mechanism 77. The plurality of lower guides 72 each have a downward inclined plane that is inclined downward toward the inner side in the width direction of the substrate 9 and that comes in contact with the peripheral edge portion of a substrate 9 held in a horizontal position to support the substrate 9 from below. The plurality of upper guides 71 each have an upward inclined plane that is inclined upward toward the inner side in the width direction and that comes in contact with the peripheral edge portion of the substrate 9 at a position above the position of contact between the plurality of lower guides 72 and the substrate 9 so as to catch and hold the substrates 9 between the plurality of lower guides 72 and the plurality of upper guides 71. The inversion mechanism 80 rotates the plurality of lower guides 72 and the plurality of upper guides 71 about the rotary shafts 82 pointing in the horizontal direction so as to invert the substrates 9 caught and held by the plurality of lower guides 72 and the plurality of upper guides 71. The guide moving mechanism 74 advances and retracts the plurality of lower guides 72 and the plurality of upper guides 71 between the contact positions at which the guides come in contact with the substrates 9 and the retracted positions that are further away from the substrates 9 than the contact positions. The switching mechanism 77 changes the states of contact between the plurality of lower guides 72 and the substrate 9 and between the plurality of upper guides 71 and the substrate 9.

Each lower guide 72 includes the first lower contact region 721 and the second lower contact region 722. The first lower contact region 721 and the second lower contact region 722 are switched by the switching mechanism 77 and selectively serve as the downward inclined plane. Each upper guide 71 includes the first upper contact region 711 and the second upper contact region 712. The first upper contact region 711 and the second upper contact region 712 are switched by the switching mechanism 77 and selectively serve as the upward inclined plane.

With the substrate inverting device 100, the regions of contact between the guide part 73 (i.e., the upper guides 71 and the lower guides 72) and the substrates 9 can be switched in accordance with the states (e.g., unprocessed or processed) of the substrates 9. Specifically, the region of contact between each upper guide 71 and a substrate 9 can be switched between the first upper contact region 711 and the second upper contact region 712. Also, the region of contact between each lower guide 72 and a substrate 9 can be switched between the first lower contact region 721 and the second lower contact region 722. As a result, for example, it is possible to prevent grime, particles, or the like on unprocessed substrates 9 from adhering to processed substrates 9 via the regions of contact between the guide part 73 and the substrate 9.

In the substrate inverting device 100, the first lower contact region 721 and the second lower contact region 722 of each lower guide 72 are disposed at the same position in the longitudinal direction of the lower rotary shaft 76 extending in the width direction. Also, the first upper contact region 711 and the second upper contact region 712 of each upper guide 71 are disposed at the same position in the longitudinal direction of the upper rotary shaft 75 extending in the width direction. The switching mechanism 77 includes the lower guide rotation mechanisms 772 and the upper guide rotation mechanisms 771. The lower guide rotation mechanisms 772 rotate each lower guide 72 about the lower rotary shaft 76 so as to make the first lower contact region 721 and the second lower contact region 722 selectively serve as the aforementioned downward inclined plane. The upper guide rotation mechanisms 771 rotate each upper guide 71 about the upper rotary shaft 75 so as to make the first upper contact region 711 and the second upper contact region 712 selectively serve as the aforementioned upward inclined plane.

Accordingly, the first lower contact region 721 and the second lower contact region 722 of each lower guide 72 can easily be switched. Also, the first upper contact region 711 and the second upper contact region 712 of each upper guide 71 can easily be switched.

As described above, the lower guide rotation mechanisms 772 rotate each lower guide 72 by 180 degrees about the lower rotary shaft 76 so as to make the first lower contact region 721 and the second lower contact region 722 selectively serves as the aforementioned downward inclined plane. Also, the upper guide rotation mechanisms 271 rotate each upper guide 71 by 180 degrees about the upper rotary shaft 75 so as to make the first upper contact region 711 and the second upper contact region 712 selectively serve as the aforementioned upward inclined plane.

In this way, when the first lower contact region 721 and the second lower contact region 722 of each lower guide 72 are disposed with a relatively large interval therebetween, it is possible to suppress a transfer of grime, particles, or the like between the first lower contact region 721 and the second lower contact region 722. Also, when the first upper contact region 711 and the second upper contact region 712 of each upper guide 71 are disposed with a relatively large interval therebetween, it is possible to suppress a transfer of grime, particles, or the like between the first upper contact region 711 and the second upper contact region 712.

The substrate processing apparatus 1 includes the substrate inverting device 100, the back-surface cleaning processing parts 24, and the transport robot 22 serving as a substrate transporter. The back-surface cleaning processing parts 24 clean the back surfaces of substrates 9 inverted by the substrate inverting device 100. The transport robot 22 transports substrates 9 between the substrate inverting device 100 and the back-surface cleaning processing parts 24. As described above, in the substrate inverting device 100, the regions of contact between the guide part 73 and substrates 9 can be switched in accordance with the states of the substrates 9. Accordingly, the inversion of unprocessed substrates 9 and the inversion of substrates 9 that have undergone back-surface cleaning processing can be implemented by one and the same substrate inverting device 100 while preventing the adhesion of particles or the like to the substrates 9. As a result, the time required to process substrates 9 can be shortened. Moreover, the size of the substrate processing apparatus 1 can be reduced, as compared with the case where a plurality of substrate inverting devices are provided in accordance with the states of substrates 9.

As described above, the substrate processing apparatus 1 further includes the cleaning processing cell 20, which is a cleaning processing block, and the indexer cell 10, which is an indexer block. The back-surface cleaning processing parts 24 and the transport robot 22 serving as a substrate transporter are disposed in the cleaning processing cell 20. The transfer robot 12 serving as another substrate transporter is disposed in the indexer cell 10. The indexer cell 10 passes unprocessed substrates 9 to the cleaning processing cell 20 and receives processed substrates 9 from the cleaning processing cell 20. The substrate inverting device 100 is disposed at the connection between the cleaning processing cell 20 and the indexer cell 10. In the case where one transporter out of the transport robot 22 and the transfer robot 12 transports substrates 9 into the substrate inverting device 100, the substrates 9 inverted by the substrate inverting device 100 are transported out of the substrate inverting device 100 by the other transporter. In this way, the substrate inverting device 100 is used to invert substrates 9 and to receive and pass substrates 9 between the indexer cell 10 and the cleaning processing cell 20. This further shortens the time required for the substrate processing apparatus 1 to process substrates 9.

The substrate processing apparatus 1 does not necessarily have to perform cleaning processing on the front and back surfaces of substrates 9, and for example, may perform cleaning processing on only the front surfaces of substrates 9 by using the front-surface cleaning processing parts 23. Alternatively, the substrate processing apparatus 1 may perform cleaning processing on only the back surfaces of substrates 9 by using the back-surface cleaning processing parts 24.

In the case where the substrate processing apparatus 1 performs cleaning processing on only the back surfaces of substrates 9, the substrates 9 that have undergone back-surface cleaning processing performed in the cleaning processing cell 20 are transported into the substrate inverting device 100 by the transport robot 22, inverted by the substrate inverting device 100, and then transported out by the transfer robot 12 of the indexer cell 10. In this case as well, the time required to process substrates 9 can be further shortened as described above.

Although in the aforementioned example, each upper guide 71 is located vertically above each lower guide 72, each upper guide 71 may be disposed at a position different from the position of each lower guide 72 in plan view. For example, in the example illustrated in FIG. 17, each upper guide 71 is located at a position different from the positions of two lower guides 72 in the circumferential direction about a central axis that extends in the up-down direction through the center of a substrate 9, and does not overlap with the lower guides 72 in the up-down direction. Each upper guide 71 is disposed adjacent to the lower guides 72 in the circumferential direction. The two upper guides 71 are disposed at positions shifted by 180 degrees in the circumferential direction. The two lower guides 72 are also disposed at positions shifted by 180 degrees in the circumferential direction.

In this way, when each upper guide 71 is disposed at a position different from the position of each lower guide 72 in plan view, it is possible to suppress the occurrence of a situation where the movable range of one of the upper guides 71 and the lower guides 72 is restricted by the other in the case where the switching mechanism 77 (see FIG. 4) changes the states of contact between the upper guides 71 and substrates 9 and between the lower guides 72 and the substrates 9. Specifically, it is possible to suppress the occurrence of a situation where the rotation of the upper guides 71 by the switching mechanism 77 is mechanically restricted by the presence of the lower guides 72. It is also possible to suppress the occurrence of a situation where the rotation of the lower guides 72 by the switching mechanism 77 is mechanically restricted by the presence of the upper guides 71. As a result, the regions of contact between the guide part 73 (i.e., the upper guides 71 and the lower guides 72) and substrates 9 can easily be switched.

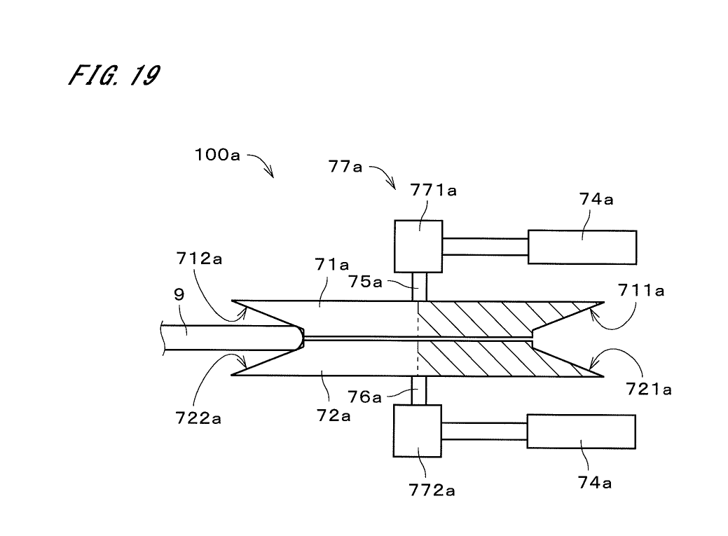

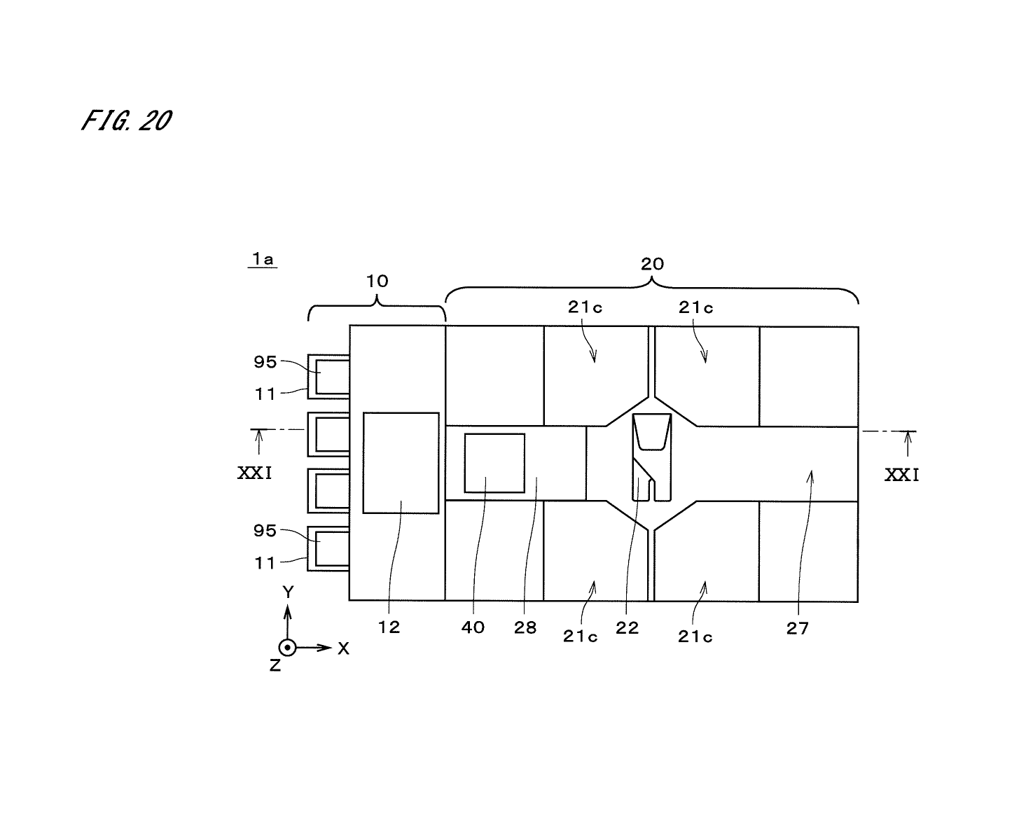

Next, another preferable substrate inverting device will be described. FIGS. 18 and 19 illustrate one set of an upper guide 71a and a lower guide 72a in a substrate inverting device 100a. The other upper guides 71a and the other lower guides 72a also have the same structures as those illustrated in FIGS. 18 and 19. Constituent elements of the substrate inverting device 100a that are not shown are approximately the same as those of the substrate inverting device 100 described above.

Each lower guide 72a is located vertically below the upper guide 71a. Each lower guide 72a has approximately the same shape as the upper guide 71a, and the lower guide 72a is upside down from the upper guide 71a. An upper rotary shaft 75a that extends in the up-down direction is connected to the central portion of the upper surface of the upper guide 71a in the width direction. A lower rotary shaft 76a that extends in the up-down direction is connected to the central portion of the lower surface of the lower guide 72a in the width direction.

The upper guide 71a includes a first upper contact region 711a and a second upper contact region 712a. The first upper contact region 711a and the second upper contact region 712a are disposed at the same position in the longitudinal direction of the upper rotary shaft 75a (i.e., up-down direction). In the state illustrated in FIG. 18, the first upper contact region 711a is an inclined plane that is inclined upward toward the radial inner side (i.e., the inner side in the width direction of the substrate 9) from the outer edge of the substrate 9. The second upper contact region 712a is located radially outward of the first upper contact region 711a. The second upper contact region 712a is an inclined plane that is inclined upward toward the outer side in the width direction. The first upper contact region 711a and the second upper contact region 712a have approximately the same shape, except that they are inverted from right to left.

The lower guide 72a includes a first lower contact region 721a and a second lower contact region 722a. In the state illustrated in FIG. 18, the first lower contact region 721a is an inclined plane that is inclined downward toward the inner side in the width direction from the outer edge of the substrate 9. The second lower contact region 722a is located radially outward of the first lower contact region 721a. The second lower contact region 722a is an inclined plane that is inclined downward toward the outer side in the width direction. The first lower contact region 721a and the second lower contact region 722a have approximately the same shape, except that they are inverted from right to left.

In FIG. 18, a portion where the first upper contact region 711a is provided out of the right and left halves of the upper guide 71a and a portion where the first lower contact region 721a is provided out of the right and left halves of the lower guide 72a are indicated by diagonal parallel lines. The same applies to FIG. 19, which will be described later.

In the state illustrated in FIG. 18, the first upper contact region 711a of the upper guide 71a and the first lower contact region 721a of the lower guide 72a face each other in the up-down direction and come in contact with the peripheral edge portion of the substrate 9. That is, the first upper contact region 711a serves as an upper contact surface of the upper guide 71a that comes in contact with the peripheral edge portion of the substrate 9. This upper contact surface is inclined upward toward the inner side in the width direction of the substrate 9. The first lower contact region 721a serves as a lower contact surface of the lower guide 72a that comes in contact with the peripheral edge portion of the substrate 9. This lower contact surface is inclined downward toward the inner side in the width direction of the substrate 9. Each lower contact surface comes in contact with the peripheral edge portion of the substrate 9 held in a horizontal position and supports the substrate 9 from below. Each upper contact surface comes in contact with the peripheral edge portion of the substrate 9 held in a horizontal position at a position above the position of contact between the substrate 9 and the lower contact surface.

In the substrate inverting device 100a, each upper guide rotation mechanism 771a of the switching mechanism 77a rotates the upper guide 71a horizontally 180 degrees about the upper rotary shaft 75a so as to switch the positions of the first upper contact region 711a and the second upper contact region 712a. In other words, the upper guide rotation mechanism 771a inverts the upper guide 71a from right to left. Accordingly, as illustrated in FIG. 19, the second upper contact region 712a is positioned radially inward of the first upper contact region 711a. In the state illustrated in FIG. 19, the second upper contact region 712a serves as an upper contact surface that is inclined upward toward the inner side in the width direction of the substrate 9 and that comes in contact with the peripheral edge portion of the substrate 9. The first upper contact region 711a is inclined upward toward the outer side in the width direction of the substrate 9.

Also, a lower guide rotation mechanism 772a of the switching mechanism 77a illustrated in FIG. 18 rotates the lower guide 72a horizontally 180 degrees about the lower rotary shaft 76a so as to switch the positions of the first lower contact region 721a and the second lower contact region 722a. In other words, the lower guide rotation mechanism 772a inverts the lower guide 72a from right to left. Accordingly, as illustrated in FIG. 19, the second lower contact region 722a is positioned radially inward of the first lower contact region 721a. In the state illustrated in FIG. 19, the second lower contact region 722a serves as a lower contact surface that is inclined downward toward the inner side in the width direction of the substrate 9 and that comes in contact with the peripheral edge portion of the substrate 9. The first lower contact region 721a is inclined upward toward the outer side in the width direction of the substrate 9.

In this way, in the substrate inverting device 100a, the upper guide rotation mechanisms 771a of the switching mechanism 77a make the first upper contact regions 711a and the second upper contact regions 712a of the upper guides 71a selectively serve as upper contact surfaces. Also, the lower guide rotation mechanisms 772a of the switching mechanism 77a make the first lower contact regions 721a and the second lower contact regions 722a of the lower guides 72a selectively serve as lower contact surfaces. That is, the switching mechanism 77a changes the states of contact between each upper guide 71a and a substrate 9 and between each lower guide 72a and the substrate 9.

Also, in the substrate inverting device 100a, guide moving mechanisms 74a are connected to the upper guide rotation mechanisms 771a and the lower guide rotation mechanisms 772a. The guide moving mechanisms 74a move the upper guide rotation mechanisms 771a and the lower guide rotation mechanisms 772a in the width direction, so that each upper guide 71a and each lower guide 72a advance and retract between contact positions at which the guides come in contact with substrates 9 and retracted positions that are further away from the substrates 9 on the outer side in the width direction (i.e., radially outward of the substrate 9) than the contact positions.

As described above, in the substrate inverting device 100a, the first lower contact region 721a and the second lower contact region 722a of each lower guide 72a are disposed at positions that have line symmetry with respect to the lower rotary shaft 76a extending in the up-down direction. Also, the first upper contact region 711a and the second upper contact region 712a of each upper guide 71a are disposed at positions that have line symmetry with respect to the upper rotary shaft 75a extending in the up-down direction. The switching mechanism 77a includes the lower guide rotation mechanisms 772a and the upper guide rotation mechanisms 771a. The lower guide rotation mechanisms 772a rotate each lower guide 72a about the lower rotary shaft 76a so as to make the first lower contact region 721a and the second lower contact region 722a selectively serve as the aforementioned downward inclined plane. The upper guide rotation mechanisms 771a rotate each upper guide 71a about the upper rotary shaft 75a so as to make the first upper contact region 711a and the second upper contact region 712a selectively serve as the aforementioned upward inclined plane.

Accordingly, as in the substrate inverting device 100, the first lower contact region 721a and the second lower contact region 722a of each lower guide 72a can easily be switched. Also, the first upper contact region 711a and the second upper contact region 712a of each upper guide 71a can easily be switched.

As described above, the lower guide rotation mechanisms 772a rotate each lower guide 72a by 180 degrees about the lower rotary shaft 76a so as to make the first lower contact region 721a and the second lower contact region 722a selectively serve as the aforementioned downward inclined plane. Also, the upper guide rotation mechanisms 771a rotate each upper guide 71a by 180 degrees about the upper rotary shaft 75a so as to make the first upper contact region 711a and the second upper contact region 712a selectively serve as the aforementioned upward inclined plane.

In this way, if the first lower contact region 721a and the second lower contact region 722a of each lower guide 72a are disposed with a relatively large interval therebetween, it is possible to suppress a transfer of grime, particles, or the like between the first lower contact region 721a and the second lower contact region 722a. Also, if the first upper contact region 711a and the second upper contact region 712a of each upper guide 71a are disposed with a relatively large interval therebetween, it is possible to suppress a transfer of grime, particles, or the like between the first upper contact region 711a and the second upper contact region 712a.

Although each upper guide 71a described above is located vertically above the lower guide 72a, each upper guide 71a may be disposed at a position different from the position of each lower guide 72a in plan view as in the example illustrated in FIG. 17. In this case, the regions of contact between the upper guides 71a and substrates 9 and between the lower guides 72a and the substrates 9 can easily be switched in the same manner as described above.

The substrate inverting devices 100 and 100a and the substrate processing apparatus 1 described above can be modified in various ways.

The shapes of the upper guides 71 and 71a and the lower guides 72 and 72a are not limited to the examples illustrated in FIGS. 7 and 18, and may be changed in various ways. For example, the upper guide 71 illustrated in FIG. 7 may further include a third upper contact region, in addition to the first upper contact region 711 and the second upper contact region 712. The first upper contact region 711, the second upper contact region 712, and the third upper contact region are disposed at approximately the same position in the longitudinal direction of the upper rotary shaft 75 (i.e., horizontal position) and at 120-degree intervals in the circumferential direction about the upper rotary shaft 75. The same applies to the lower guides 72. Accordingly, the regions of contact between the upper guides 71 and substrates 9 and between the lower guides 72 and the substrates 9 can be switched in accordance with the three types of states of the substrates 9.

Also, for example, the upper guide 71a illustrated in FIG. 18 may further include a third upper contact region, in addition to the first upper contact region 711a and the second upper contact region 712a. The first upper contact region 711a, the second upper contact region 712a, and the third upper contact region are disposed at approximately the same position in the longitudinal direction of the upper rotary shaft 75a (i.e., up-down direction) and at 120-degree intervals in the circumferential direction about the upper rotary shaft 75a. The same applies to the lower guides 72a. Accordingly, the regions of contact between the upper guides 71a and substrates 9 and between the lower guides 72a and the substrates 9 can be switched in accordance with the three types of states of the substrates 9. Each of the upper guides 71 and 71a and the lower guides 72 and 72a may include four or more contact regions.

The direction in which the upper guides 71 and 71a and the lower guides 72 and 72a are advanced and retracted by the guide moving mechanisms 74 and 74a is not limited to the horizontal direction, and may be changed in various ways. For example, the direction in which the upper guides 71 and 71a and the lower guides 72 and 72a are advanced and retracted may be an oblique direction that is inclined to the up-down direction and the width direction.

In the substrate processing apparatus 1, the arrangement and numbers of the front-surface cleaning processing parts 23, the back-surface cleaning processing parts 24, and the placement parts 41 may be appropriately changed. The substrate inverting devices 100 and 100a do not necessary have to be disposed at the connection between the indexer cell 10 and the cleaning processing cell 20. The positions of the substrate inverting devices 100 and 100a may also be appropriately changed.

The substrate inverting devices 100 and 100a may be used in substrate processing apparatuses other than the substrate processing apparatus 1 that performs scrub cleaning on substrates 9. For example, the substrate inverting devices 100 and 100a may be used in a coater and developer in which a processing block that performs resist coating processing on substrates and a processing block that performs development processing on substrates are disposed side by side via a substrate receiving/passing part.

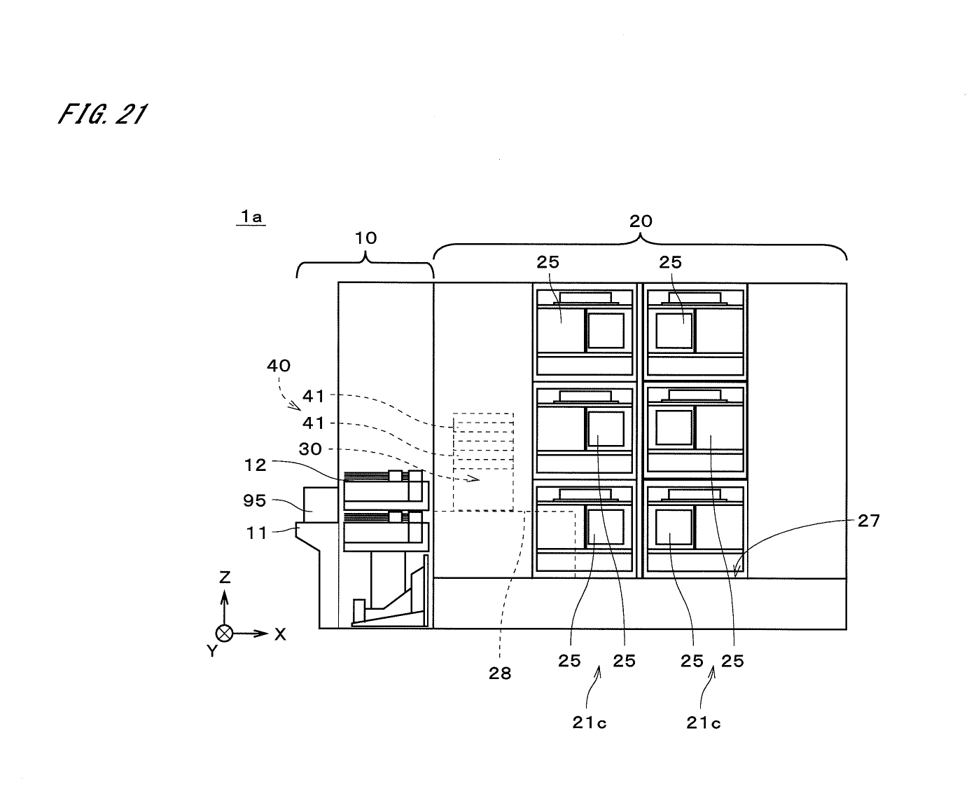

Also, the substrate inverting devices 100 and 100a may be used in a substrate processing apparatus 1a illustrated in FIGS. 20 and 21. This substrate processing apparatus 1a is a substrate processing apparatus capable of performing processing such as cleaning processing, dry processing, and etching processing using various types of chemical solutions. FIG. 20 is a plan view of the substrate processing apparatus 1a. FIG. 21 is a view of the substrate processing apparatus 1a taken along line XXI-XXI in FIG. 20. In FIG. 21, some constituent elements that are present in front of line XXI-XXI are also shown by broken lines.

Like the substrate processing apparatus 1 illustrated in FIG. 1, the substrate processing apparatus 1a includes an indexer cell 10 and a cleaning processing cell 20. The indexer cell 10 includes four carrier stages 11 and a transfer robot 12. Each carrier stage 11 has placed thereon a carrier 95 that can house a plurality of substrates 9.

The cleaning processing cell 20 includes a transport robot 22, four cleaning processing units 21c, an inversion unit 30, and a placement unit 40. The transport robot 22 moves on a path 27 that extends in the X direction at the center of the cleaning processing cell 20 in the Y direction. The transport robot 22 serves as a substrate transporter that receives and passes substrates 9 among the inversion unit 30, the placement unit 40, and the cleaning processing units 21c. The four cleaning processing units 21c are disposed around the central portion of the cleaning processing cell 20. Among the four cleaning processing units 21c, two cleaning processing units 21c are disposed on the +Y side of the path 27, and the other two cleaning processing units 21c are disposed on the −Y side of the path 27. Each cleaning processing unit 21c includes three cleaning processing parts 25 that are stacked one above another in the up-down direction. That is, the cleaning processing cell 20 includes 12 cleaning processing parts 25. The cleaning processing parts 25 can perform processing such as cleaning processing and etching processing using, for example, SC1 (a mixed solution of ammonia and hydrogen peroxide), SC2 (a mixed solution of hydrochloric acid and a hydrogen peroxide solution), BHF (a mixed solution of hydrofluoric acid and ammonium fluoride), HF (hydrofluoric acid), SPM (a mixed solution of sulfuric acid and a hydrogen peroxide solution), a mixed solution of hydrofluoric acid and nitric acid, and ultrapure water and dry processing using isopropyl alcohol (IPA).

The inversion unit 30 and the placement unit 40 are disposed on a pedestal 28 that is disposed at the end portion on the −X side of the path 27. The inversion unit 30 is deposed on the pedestal 28. The placement unit 40 is disposed on the inversion unit 30. As described above, the placement unit 40 includes a plurality of placement parts 41 and used to receive and pass substrates 9 from and to the indexer cell 10. The inversion unit 30 inverts unprocessed substrates 9 received from the indexer cell 10 upside down (i.e., inverts the front and back surfaces of the unprocessed substrates 9 by 180 degrees), and then passes the unprocessed substrates 9 to the cleaning processing cell 20. The inversion unit 30 also passes processed substrates 9 received from the cleaning processing cell 20 to the indexer cell 10 or the cleaning processing cell 20.

With this configuration of the substrate processing apparatus 1a, for example, the transport and processing of substrates are performed in the following manner by way of example.

First, the transfer robot 12 of the indexer cell 10 passes unprocessed substrates from the indexer cell 10 to the inversion unit 30. In the inversion unit 30, the front and back surfaces of the received substrates 9 are inverted by 180 degrees, so that the back surfaces of the substrates 9 face upward. Then, the transport robot 22 of the cleaning processing cell 20 receives the substrates 9 from the inversion unit 30 and transports the substrates 9 into the cleaning processing parts 25 in one of the cleaning processing units 21c. In the cleaning processing parts 25, for example, SC1 is supplied as a cleaning liquid to the back surfaces of the substrates 9 that face upward so as to clean unnecessary organic matter adhering to the back surfaces of the substrates 9, and a solution of fluoro-nitric acid is further supplied to the back surfaces of the substrates 9 that face upward so as to etch unnecessary metal films adhering to the back surfaces of the substrates 9. The substrates 9 that have undergone the processing performed in the cleaning processing parts 25 are transported out of the cleaning processing parts 25 and again transported into the inversion unit 30 by the transport robot 22. In the inversion unit 30, the front and back surfaces of the substrates 9 are inverted by 180 degrees, so that the front surfaces of the substrates 9 face upward. Thereafter, the substrates 9 are taken out of the inversion unit 30 by the transfer robot 12 of the indexer cell 10 and housed in a carrier 95 of the indexer cell 10.

In the case of this substrate processing apparatus 1a as well, the substrate inverting device 100 including the inversion unit 30 can properly use the first upper contact regions of the upper guides 71 and the first lower contact regions of the lower guides 72 that come in contact with unprocessed substrates 9 and the second upper contact regions of the upper guides 71 and the second lower contact regions of the lower guides 72 that come in contact with processed substrates 9, thus preventing grime, particles, or the like on the unprocessed substrates 9 from adhering to the clean processed substrates 9 via the regions of contact between the upper guides 71 and the substrates 9 and between the lower guides 72 and the substrates 9.

The substrate inverting devices 100 and 100a do not necessarily have to be part of a substrate processing apparatus, and may be used alone. Also, a device obtained by removing the inversion mechanism 80 from the substrate inverting device 100 or 100a may be used as a substrate catch-and-hold device.

The substrate catch-and-hold device includes, for example, a plurality of upper guides 71, a plurality of lower guides 72, and a switching mechanism 77. The plurality of lower guides 72 each have a downward inclined plane that is inclined downward toward the inner side in the width direction of a substrate 9 and that comes in contact with the peripheral edge portion of the substrate 9 held in a horizontal position to support the substrate 9 from below. The plurality of upper guides 71 each have an upward inclined plane that is inclined upward toward the inner side in the width direction and that comes in contact with the peripheral edge portion of a substrate 9 at a position above the position of contact between the plurality of lower guides 72 and substrate 9 to catch and hold the substrates 9 between the plurality of lower guides 72 and the plurality of upper guides 72. The switching mechanism 77 changes the states of contact between the plurality of lower guides 72 and substrates 9 and between the plurality of upper guides 71 and the substrate 9.

Each lower guide 72 includes a first lower contact region 721 and a second lower contact region 722. The first lower contact region 721 and the second lower contact region 722 are switched by the switching mechanism 77 and selectively serve as the downward inclined plane. Each upper guide 71 includes a first upper contact region 711 and a second upper contact region 712. The first upper contact region 711 and the second upper contact region 712 are switched by the switching mechanism 77 and selectively serve as the upward inclined plane.

In the substrate catch-and-hold device, the regions of contact between the upper guides 71 and substrates 9 and between the lower guides 72 and the substrates 9 can be switched in accordance with the states (e.g., unprocessed or processed) of the substrates 9. As a result, for example, it is possible to prevent grime, particles, or the like on unprocessed substrates 9 from adhering to processed substrates 9 via the regions of contact between the upper guides 71 and the substrates 9 and between the lower guides 72 and the substrates 9.

As one specific embodiment, this substrate catch-and-hold device can be disposed in the placement unit 40 and used to transport and process substrates 9.

In this case, first, the transfer robot 12 of the indexer cell 10 transports unprocessed substrates 9, with their front surfaces facing upward, from the indexer cell 10 into the substrate catch-and-hold device in the placement unit 40. The transport robot 22 of the cleaning processing cell 20 receives the substrates 9, with their front surfaces facing upward, from the catch-and-hold device in the placement unit 40 and transports the substrates 9 out of the placement unit 40. Then, the transport robot 22 transports the substrates 9 transported out of the placement unit 40 into the cleaning processing parts 25 in one of the cleaning processing units 21c. In the cleaning processing parts 25, for example, processing for supplying hydrofluoric acid or a mixed solution of hydrofluoric acid and nitric acid to bevel parts of the substrates 9 and etching metal-containing films or the like adhering to the bevel parts is performed, with the front surfaces of the substrates 9 facing upward.

The substrates 9 that have undergone the processing performed in the cleaning processing parts 25 are transported out of the cleaning processing parts 25 and again transported into the substrate catch-and-hold device in the placement unit 40 by the transport robot 22. Thereafter, the transfer robot 12 of the indexer cell 10 receives the substrates 9, with their front surfaces facing upward, from the substrate catch-and-hold device in the placement unit 40 and houses the substrates 9 in a carrier 95 of the indexer cell 10.

In this case as well, the substrate catch-and-hold device disposed in the placement unit 40 can properly use the first upper contact regions of the upper guides 71 and the first lower contact regions of the lower guides 72 that come in contact with unprocessed substrates 9 and the second upper contact regions of the upper guides 71 and the second lower contact regions of the lower guides 72 that come in contact with processed substrates 9, thus preventing grime, particles, or the like on the unprocessed substrates 9 from adhering to the clean processed substrates 9 via the regions of contact between the upper guides 71 and the substrates 9 and between the lower guides 72 and the substrates 9.

The substrate catch-and-hold device, the substrate inverting devices 100 and 100a, and the substrate processing apparatuses 1 and 1a described above may also handle, in addition to semiconductor substrates, glass substrates for use in flat panel displays such as liquid crystal displays and organic electroluminescent (EL) displays or glass substrates for use in other displays. Also, the substrate catch-and-hold device, the substrate inverting devices 100 and 100a, and the substrate processing apparatuses 1 and 1a described above may handle other substrates such as optical disk substrates, magnetic disk substrates, magneto-optical disk substrates, photomask substrates, ceramic substrates, and solar-cell substrates.

The configurations of the preferred embodiments and variations described above may be appropriately combined as long as there are no mutual inconsistencies.

While the invention has been shown and described in detail, the foregoing description is in all aspects illustrative and not restrictive. It is therefore to be understood that numerous modifications and variations can be devised without departing from the scope of the invention. This application claims priority benefit under 35 U.S.C. Section 119 of Japanese Patent Application No. 2017-183211 filed in the Japan Patent Office on Sep. 25, 2017, the entire disclosure of which is incorporated herein by reference.

### REFERENCE SIGNS LIST

1, 1a Substrate processing apparatus
9 Substrate
10 Indexer cell
1 Transfer robot
20 Cleaning processing cell
22 Transport robot
24 Back-surface cleaning processing part
71, 71a Upper guide
72, 72a Lower guide
74, 74a Guide moving mechanism
75, 75a Upper rotary shaft
76, 76a Lower rotary shaft
77, 77a Switching mechanism
80 Inversion mechanism
82 Rotary shaft
100, 100a Substrate inverting device
711, 711a First upper contact region
712, 712a Second upper contact region
721, 721a First lower contact region
722, 722a Second lower contact region
771, 771a Upper guide rotation mechanism
772, 772a Lower guide rotation mechanism

1. A substrate inverting device comprising:
a plurality of lower guides each having a downward inclined plane that is inclined downward toward an inner side in a width direction of a substrate and that comes in contact with a peripheral edge portion of said substrate held in a horizontal position to support said substrate from below;
a plurality of upper guides each having an upward inclined plane that is inclined upward toward the inner side in said width direction and that comes in contact with the peripheral edge portion of said substrate at a position above a position of contact between said substrate and said plurality of lower guides to catch and hold said substrate between said plurality of lower guides and said plurality of upper guides;
an inversion mechanism that inverts said substrate that is caught and held by said plurality of lower guides and said plurality of upper guides, by rotating said plurality of lower guides and said plurality of upper guides about a central axis pointing in a horizontal direction;
a guide moving mechanism that advances and retracts said plurality of lower guides and said plurality of upper guides between contact positions and retracted positions, said contact positions being positions at which said plurality of lower guides and said plurality of upper guides are in contact with said substrate, and said retracted positions being positions that are further away from said substrate than said contact positions; and
a switching mechanism that changes states of contact between said plurality of lower guides and said substrate and between said plurality of upper guides and said substrate,
wherein each lower guide includes a first lower contact region and a second lower contact region that are switched by said switching mechanism and selectively serve as said downward inclined plane, and
each upper guide includes a first upper contact region and a second upper contact region that are switched by said switching mechanism and selectively serve as said upward inclined plane.

2. The substrate inverting device according to claim 1, wherein
said first lower contact region and said second lower contact region of said each lower guide are disposed at the same position in a longitudinal direction of a lower rotary shaft that extends in said width direction,
said first upper contact region and said second upper contact region of said each upper guide are disposed at the same position in a longitudinal direction of an upper rotary shaft that extends in said width direction, and
said switching mechanism includes:
a lower guide rotation mechanism that rotates said each lower guide about said lower rotary shaft to make said first lower contact region and said second lower contact region selectively serve as said downward inclined plane; and
an upper guide rotation mechanism that rotates said each upper guide about said upper rotary shaft to make said first upper contact region and said second upper contact region selectively serve as said upward inclined plane.

3. The substrate inverting device according to claim 2, wherein
said lower guide rotation mechanism rotates said each lower guide 180 degrees about said lower rotary shaft to make said first lower contact region and said second lower contact region selectively serve as said downward inclined plane, and
said upper guide rotation mechanism rotates said each upper guide 180 degrees about said upper rotary shaft to make said first upper contact region and said second upper contact region selectively serve as said upward inclined plane.

4. The substrate inverting device according to claim 1, wherein
said first lower contact region and said second lower contact region of said each lower guide are disposed at positions that have line symmetry with respect to a lower rotary shaft that extends in an up-down direction,
said first upper contact region and said second upper contact region of said each upper guide are disposed at positions that have line symmetry with respect to an upper rotary shaft that extends in said up-down direction, and
said switching mechanism includes:
a lower guide rotation mechanism that rotates said each lower guide about said lower rotary shaft to make said first lower contact region and said second lower contact region selectively serve as said downward inclined plane; and
an upper guide rotation mechanism that rotates said each upper guide about said upper rotary shaft to make said first upper contact region and said second upper contact region selectively serve as said upward inclined plane.

5. The substrate inverting device according to claim 4, wherein
said lower guide rotation mechanism rotates said each lower guide 180 degrees about said lower rotary shaft to make said first lower contact region and said second lower contact region selectively serve as said downward inclined plane, and
said upper guide rotation mechanism rotates said each upper guide 180 degrees about said upper rotary shaft to make said first upper contact region and said second upper contact region selectively serve as said upward inclined plane.

6. The substrate inverting device according to claim 1, wherein
said each upper guide is disposed at a position different from a position of said each lower guide in plan view.

7. A substrate processing apparatus comprising:
the substrate inverting device according to claim 1;
a back-surface cleaning part that cleans a back surface of said substrate inverted by said substrate inverting device; and
a substrate transporter that transports said substrate between said substrate inverting device and said back-surface cleaning part.

8. The substrate processing apparatus according to claim 7, further comprising:
a cleaning processing block in which said back-surface cleaning part and said substrate transporter are disposed; and
an indexer block in which another substrate transporter is disposed and that passes an unprocessed substrate to said cleaning processing block and receives a processed substrate from said cleaning processing block,
wherein said substrate inverting device is disposed at a connection between said cleaning processing block and said indexer block, and
in a case where one transporter out of said substrate transporter and said another substrate transporter transports a substrate into said substrate inverting device, said substrate inverted by said substrate inverting device is transported out of said substrate inverting device by the other substrate transporter.

9. A substrate catch-and-hold device comprising:
a plurality of lower guides each having a downward inclined plane that is inclined downward toward an inner side in a width direction of a substrate and that comes in contact with a peripheral edge portion of said substrate held in a horizontal position to support said substrate from below;
a plurality of upper guides each having an upward inclined plane that is inclined upward toward the inner side in said width direction and that comes in contact with the peripheral edge portion of said substrate at a position above a position of contact between said substrate and said plurality of lower guides to catch and hold said substrate between said plurality of lower guides and said plurality of upper guides; and
a switching mechanism that changes states of contact between said plurality of lower guides and said substrate and between said plurality of upper guides and said substrate,
wherein each lower guide includes a first lower contact region and a second lower contact region that are switched by said switching mechanism and selectively serve as said downward inclined plane, and
each upper guide includes a first upper contact region and a second upper contact region that are switched by said switching mechanism and selectively serve as said upward inclined plane.
